(19) United States
(12) Patent Application Publication
(10) Pub. No.: US 2026/0079881 A1
(43) Pub. Date: Mar. 19, 2026

(54) CONFIGURABLE WAVEFRONT PARALLEL PROCESSOR

(71) Applicant: Nokia Solutions and Networks Oy, Espoo (FI)

(72) Inventors: Joseph GALARO, Murray Hill, NJ (US); Hungkei CHOW, Murray Hill, NJ (US)

(21) Appl. No.: 19/109,660

(22) PCT Filed: Sep. 9, 2022
(86) PCT No.: PCT/US2022/076162

§ 371 Date: Mar. 7, 2025

(51) Int. Cl. G06F 15/82; G06F 9/30

(52) U.S. Cl. CPC G06F 15/825; G06F 9/3001

(57) ABSTRACT

An apparatus comprising: at least one processing element configured to process a data flow in at least one direction of a plurality of directions; a configuration register comprising at least one setting that determines the processing of the data flow with the at least one processing element; and a shift register configured to select data of the at least one processing element from the at least one direction, and to provide at least one shifted data sample to a plurality of slices configured to perform at least one arithmetic operation with the data flow; wherein at least one slice of the plurality of slices is configured with the at least one setting of the configuration register.

### TECHNICAL FIELD

The examples and non-limiting example embodiments relate generally to system architecture and, more particularly, to a configurable wavefront parallel processor.

### BACKGROUND

It is known to develop processing architectures for vector operations within a communication network.

### SUMMARY

In accordance with an aspect, an apparatus includes at least one processing element configured to process a data flow in at least one direction of a plurality of directions; a configuration register comprising at least one setting that determines the processing of the data flow with the at least one processing element; and a shift register configured to select data of the at least one processing element from the at least one direction, and to provide at least one shifted data sample to a plurality of slices configured to perform at least one arithmetic operation with the data flow; wherein at least one slice of the plurality of slices is configured with the at least one setting of the configuration register.

In accordance with an aspect, a method includes processing, with at least one processing element, a data flow in at least one direction of a plurality of directions; determining at least one setting of a configuration register, the at least one setting determining the processing of the data flow with the at least one processing element; selecting, with a shift register, data of the at least one processing element from the at least one direction; providing, with the shift register, at least one shifted data sample to a plurality of slices configured to perform at least one arithmetic operation with the data flow; and performing the at least one arithmetic operation with the data flow with the plurality of slices; wherein at least one slice of the plurality of slices is configured with the at least one setting of the configuration register.

In accordance with an aspect, an apparatus includes at least one processor; and at least one memory including computer program code; wherein the at least one memory and the computer program code are configured to, with the at least one processor, cause the apparatus at least to: process, with at least one processing element, a data flow in at least one direction of a plurality of directions; determine at least one setting of a configuration register, the at least one setting determining the processing of the data flow with the at least one processing element; select, with a shift register, data of the at least one processing element from the at least one direction; provide, with the shift register, at least one shifted data sample to a plurality of slices configured to perform at least one arithmetic operation with the data flow; and perform the at least one arithmetic operation with the data flow with the plurality of slices; wherein at least one slice of the plurality of slices is configured with the at least one setting of the configuration register.

In accordance with an aspect, an apparatus includes means for processing, with at least one processing element, a data flow in at least one direction of a plurality of directions; means for determining at least one setting of a configuration register, the at least one setting determining the processing of the data flow with the at least one processing element; means for selecting, with a shift register, data of the at least one processing element from the at least one direction; means for providing, with the shift register, at least one shifted data sample to a plurality of slices configured to perform at least one arithmetic operation with the data flow; and means for performing the at least one arithmetic operation with the data flow with the plurality of slices; wherein at least one slice of the plurality of slices is configured with the at least one setting of the configuration register.

In accordance with an aspect, an integrated circuit includes at least one processing element configured to process a data flow in at least one direction of a plurality of directions; a configuration register comprising at least one setting that determines the processing of the data flow with the at least one processing element; and a shift register configured to select data of the at least one processing element from the at least one direction, and to provide at least one shifted data sample to a plurality of slices configured to perform at least one arithmetic operation with the data flow; wherein at least one slice of the plurality of slices is configured with the at least one setting of the configuration register.

In accordance with an aspect, an apparatus includes an array of multi-directionally coupled processing elements configured to process a data flow in a plurality of directions, the data flow processed in parallel with another data flow within the array; wherein at least one processing element within the array is multi-directionally coupled along four cardinal axes and four ordinal axes to a plurality of other processing elements within the array; and at least one configurable fabric switch of the at least one processing element, the at least one configurable fabric switch configured to couple the at least one processing element to another processing element within the array.

In accordance with an aspect, an apparatus includes an array of multi-directionally coupled processing elements configured to process a data flow in a plurality of directions, the data flow processed in parallel with another data flow within the array; and a configuration register comprising at least one setting that determines the processing of the data flow with at least one processing element; wherein the at least one processing element is configured with the configuration register depending on a type of the data flow.

In accordance with an aspect, an apparatus includes at least one processing element configured to process a data flow in at least one direction of a plurality of directions; a first program register file configured to control a first instruction flow within the at least one processing element, the first instruction flow used for arithmetic transfers; and a second program register file configured to control a second instruction flow within the at least one processing element, the second instruction flow used for input and output transfers; wherein the first instruction flow is separate from and processed in parallel with the second instruction flow within the at least one processing element.

In accordance with an aspect, an apparatus includes at least one processing element configured to process a data flow in at least one direction of a plurality of directions; and a shift register configured to select data of the at least one processing element from the at least one direction, and to provide at least one shifted data sample to a plurality of slices configured to perform at least one arithmetic operation with the data flow.

In accordance with an aspect, an apparatus includes a plurality of slices configured to perform at least one arithmetic operation with a data flow; a configuration register comprising at least one setting, wherein at least one slice of the plurality of slices is configured with the at least one setting of the configuration register; an asymmetric first in first out data structure to process an output of the plurality of slices; and an adder tree that performs a summation of results from the plurality of slices, the adder tree controlled with at least one input output instruction.

### BRIEF DESCRIPTION OF THE DRAWINGS

The foregoing aspects and other features are explained in the following description, taken in connection with the accompanying drawings.

FIG. 1 shows a configurable wafer fabric switch.

FIG. 2 shows multiple concurrent data flows.

FIG. 3 shows multiple concurrent workloads.

FIG. 4 shows a long configuration register.

FIG. 5 shows functional control groups of a long configuration register.

FIG. 6 shows dual program flow processing.

FIG. 7 shows an example micro code instruction set.

FIG. 8 is a table showing code size of the examples described herein compared to a RISC ISA.

FIG. 9 shows an example program 16×32 matrix multiply X 32×4 matrix.

FIG. 10 shows a sample shift register structure

FIG. 11 shows sample shift register filter configurations.

FIG. 12 shows a sample shift register operand output select.

FIG. 13 shows supported number formats.

FIG. 14 shows a vector arithmetic unit.

FIG. 15 shows a vector arithmetic unit slice.

FIG. 16 shows a configurable wafer subsystem.

FIG. 17 shows a core array processor.

FIG. 18 shows an example processing element.

FIG. 19 shows an arithmetic unit slice configured for complex operation.

FIG. 20 shows an arithmetic unit slice configured for real operation.

FIG. 21 shows an asymmetric FIFO.

FIG. 22 shows an adder tree.

FIG. 23 shows a sample shift register coupled with a compute unit.

FIG. 24 is a block diagram of one possible and non-limiting system in which the example embodiments may be practiced.

FIG. 25 is an example apparatus configured to implement the examples described herein.

FIG. 26 is an example method performed with a user equipment or network service to implement the examples described herein.

### DETAILED DESCRIPTION OF EXAMPLE EMBODIMENTS

To solve compute intensive signal processing tasks in wireless communications hardware, various parallel processor architectures have been employed. Notably, multi-core processors and systolic array processors have been used to implement these calculations. The examples described herein provide significant improvement in processing capabilities, energy and area efficiency, flexibility of configuration, and diversity of targeted applications over the state-of-the-art designs. Due to the flow nature of the processing, rather than constantly fetching operands from memory to perform calculations and then writing results back into those memories, the processor described herein takes input samples in and produces a flow of that data through an array of processing elements. This flow or wavefront of data can be configured in a variety of interconnect patterns, as data passes through a processing element it can use it as an operand for calculation.

Most signal processing algorithms used in the Radio Access Network (RAN) for 5G and 6G wireless communications extensively employ linear algebra and vector/matrix arithmetic calculations to process extremely high throughput digital signals for functions such as digital beamforming, power scaling, channel filtering, interpolation, noise cancellation, and frequency offset correction. As the number of transmit and receive antennas increase with larger massive MIMO solutions in the 5G and 6G physical layer, the processing requirements for the accelerator greatly increase. Also, as new processing algorithms are defined and the 5G and 6G standards evolve, an accelerator requires flexibility with ability to adapt without hardware redesign. These requirements need to be solved with architecture and design that minimize the operational power consumption and ASIC chip area.

Listed below are current technologies and processor architectures that are employed to perform signal processing algorithms.

Discrete implementation by logic circuits: This approach uses specially designed hardware blocks that are optimized to realize specific signal processing functions. A collection of these special purpose blocks must be integrated together to implement a complete set of wireless communication L1 functions. Each specially designed hardware block provides little or no flexibility to adapt for increased processing needs or algorithm modifications. Typically, custom hardware design approaches yield better performance, lower power and smaller area, and result in the lowest unit cost in large production. However, these approaches provide the least flexible architecture implementations as changes are difficult to implement without redesign and incurring high non-recurring development cost.

Field Programmable Gate Array (FPGA) implementation: Using configurable logic provides a more flexible signal processing approach which allows a design to be targeted into off-the-shelf hardware. Configurable logic in FPGAs provides an implementation technique that can be used to implement some of the various wireless algorithms mentioned above. These commercially available integrated circuits provide a faster path to implement or prototype signal processing hardware compared to a full custom ASIC (Application Specific Integrated Circuit) development. They provide a level of flexibility as they can be reprogrammed to adapt to changing processing requirements. But they suffer from poor circuit density requiring larger circuit footprints and their unit cost is expensive compared to custom ASIC components. While FPGA implementations have lower non-recurring cost and reprogramming is possible, they suffer from lower design density, higher power consumption and higher unit cost.

Programmable General-Purpose Processors (CPU/DSP/GPU): Fully programmable general-purpose CPUs are the most versatile approach to signal processing since the design is implemented in software. They suffer from poor performance and higher unit cost but offer low non-recurring investment for their programmability. Fully programmable general purpose CPU solutions are often realized in von Neumann architecture (which share program and data memory resources typically requiring three cycles Load/operation/store) and Harvard Architecture (providing separate program and data memory, which allow concurrent instruction and data fetch, yielding a performance improvement). While both processor architectures can be used to implement signal processing algorithms the Harvard Architecture is typically used in the class of processors designated as general-purpose Digital Signal Processors (DSP). Advanced DSP and Graphics Processing Unit (GPU) are also designed with a SIMD (Single Instruction Multiple Data) architecture to exploit data parallelism in signal or graphics processing. They provide a performance boost on vector operation but suffer from the constraint that all arithmetic units (AUs) execute the same instructions on a fixed SIMD width. Signal processing solutions in this category are typically the most flexible as they are fully software based, but as such also produce some of the slowest processing performance.

Array Processor implementations such as Systolic Array: Some parallel computing architectures such as Systolic Array Processors provide a homogeneous and monolithic network of tightly coupled processing elements (PEs), often hardwired for a specific application. PEs in this structure often perform the same operation or different operations with synchronous transfer of data. The Systolic Array implements regular algorithms efficiently by using multiple PEs that perform a task on different data streams in parallel. The array of PEs is usually structured two-dimensionally: {North, South, East, and West}. Data or a partial result flow through the structure in a predefined direction. This structure for signal processing can perform regular operations well and it provides a level of flexibility. However, because of their homogeneous structure and rigid data flow, array processors are limited to uniform calculations. Intermediate result memory storage is needed to expand such processing to more complicated algorithms.

All of these architectures can be used to implement signal processing algorithms in accelerator hardware for 5G and 6G Radio Access Network (RAN) wireless communications, but for each technology or architecture, there is a significant trade-off among flexibility/programmability, required area, power consumption and cost. The examples described herein present a novel architecture that achieves improved performance with greater adaptability while minimizing its power consumption and circuit footprint.

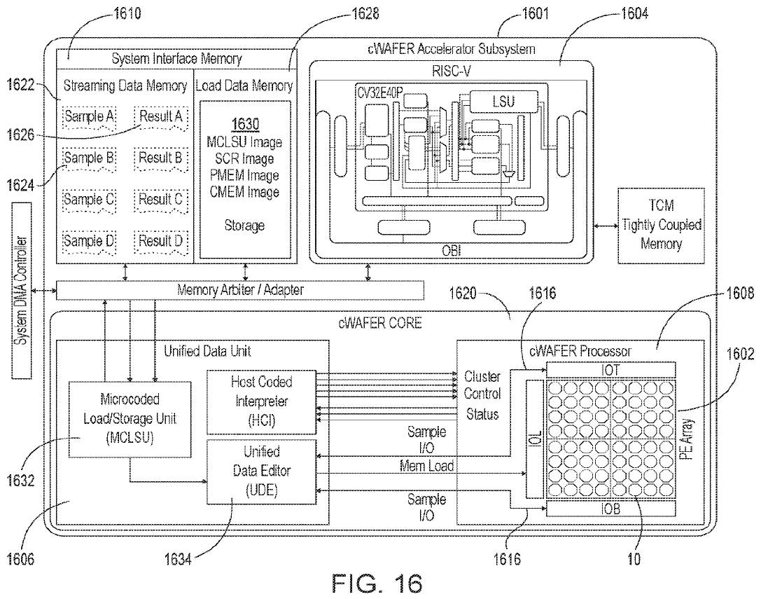

The examples described herein relate to a highly programmable, configurable, and easily scalable parallel processor architecture capable of vector/matrix signal computations targeted for ASIC (Application Specific Integrated Circuit) implementation for applications such as but not limited to wireless 5G and 6G (Layer 1, Layer 2, and DFE algorithms). The examples described herein overcome drawbacks in state-of-the-art architectures by exploiting data concurrency in a memoryless flow-based computation architecture. Each Processing Element (PE) is individually configurable and programmable, thereby providing a MIMD (Multiple Instruction Multiple Data) array architecture. In this architecture, each PE tile is connected (to its eight nearest neighbors) in a 2D array. Data and at least one program are directed to the array through independent paths of IO tiles that contain elastic buffers. Each PE contains a small internal program memory, these provide flexibility by allowing unique programs to execute on each PE tile. An enabler of the examples described herein is the use of a wide configuration register that alters the behavior of each PE, optimizing it for specific algorithms or applications. Thereby, the wide configuration register greatly simplifies programming and control of each PE. Coupled with a pre-defined nested looping program construct facility, the configuration register greatly simplifies the instruction set which achieves a significant reduction of program memory space and control logic. Internal to every PE is a fabric connectivity switch that supports data ingress, egress, and through register-to-register routing capability. This forms a dataflow structure where data samples in the flow can be intercepted at any point in a PE for internal calculations, and results can be injected back into the dataflow in every clock cycle. The connectivity fabric that unites the array of PEs is a bidirectional mesh providing I/O connection between each PE and its eight nearest neighbors along the cardinal axes {North, South, East, West} and the ordinal axes {North-east, South-east, South-west, and North-west}. The array of PE tiles can be programmed to implement a dataflow in any arbitrary direction and flow pattern that is tailored for an application. The overall array of PEs can therefore be used for a single algorithm or be partitioned to solve multiple independent problems simultaneously. This structure can also be configured to flow results from one set of PE tiles into another block of tiles for additional processing. The compute engine within the PE is a SIMD vector Arithmetic Unit (AU) that handles multiple vector elements with the same operation to easily implement matrix, vector, and scalar operations. The arithmetic performed by the AU can be configured for both real or complex numbers using either fixed-point or floating-point calculations. Multiple PEs can be employed together to form a SIMD (or vector) structure in arbitrary width, overcoming the hardware constraint found in a typical SIMD processor design. Other novel functional units within the PE include a sample shift register (SSR) that is a highly configurable register structure particularly designed for a variety of FIR filtering and correlation filtering applications, an Adder Tree and Asymmetric FiFo that are used to combine AU results and provide a non-impeding IO path for intermediate results and to maintain the pipelined computational operations. This PE array and IO tiles are supported by a data plane interface block designated as the unified data unit (UDU) (refer to FIG. 16, item 1606) and an accelerator control plane management (CPM) block containing a small general-purpose scalar processor and buffer memory. The UDU performs data access transfers between a streaming data memory and the PE tile array, it provides sample reordering and number system conversion capabilities. While the CPM supervises the overall processing by configuring and starting the chosen sub-array of PEs and relaying signaling as calculation results are available, it does not handle the data plane samples.

A distinction is made throughout this disclosure emphasizing features as configurable and/or programmable. Features that are programmable perform processing as controlled by micro-coded instructions (this is typical of many software based processors). An extension to the programmability paradigm and novelty of the examples described herein is the introduction of feature configurability where a long configuration register (LCR) modifies the internal behavior of a processing element. This configuration capability simplifies the programming and control, but also greatly reduces the chip area and power consumption.

Items 1-5 immediately following is a list of features of the system and methods described herein. A description of at least one embodiment of each feature is presented.
1. Flow-based processing architecture with memory-less flexible interconnection fabric and “data-on-the-fly” computational model yielding high computation performance at low power consumption.
2. Individually configurable processing elements utilize a long configuration register to alter behavior of PE and control program flow that optimizes for specific algorithm requirements and reduces overall power consumption.
3. A dual instruction flow provides separate control of compute engine and IO transfers coupling with a pre-defined program construct that together reduce code size and improve computation efficiency.
4. A highly configurable sample shift register structure forms a foundation for implementing a wide variety of filters with flexibility and efficiency.
5. A highly configurable and programmable vector/matrix arithmetic unit coupled with an adder tree and asymmetric FIFO form a highly versatile yet energy efficient pipelined compute unit.

1. Flow-based processing architecture. Conventional array processor architectures (e.g., systolic array) provide synchronized concurrent processing by using a network of processing elements with a limited interconnectivity. However, this architecture has a restricted or pre-defined data and processing flow. The architecture relies on sending data samples from an external memory through the processor array, and then returning the results back to a common memory. The limited connectivity restricts data flow which in turn limits processing throughput and usability.

The examples described herein greatly enhance the connectivity of the processing elements by introducing a memory-less and configurable interconnection fabric. With this enhancement, the array of PE tiles can be programmed to implement a dataflow in any arbitrary direction and flow pattern that tailor for an application. The overall array can therefore be used for a single algorithm or be partitioned to solve multiple independent problems simultaneously.

Enhanced connectivity provides flexibility for the accelerator to implement a wide variety of signal processing algorithms needed in the 5G and 6G wireless infrastructure.

More specifically, each processing element is connected via bi-directional data ports to its eight nearest neighboring PEs located along both the cardinal axes {north, east, south, west} and ordinal axes {north-east, south-east, south-west, north-west}, thus doubling the PE tile connectivity resources over a typical 2D array increasing signal routing and flow capacity. Connectivity is facilitated through a configurable fabric switch (integral to each PE) that supports data ingress, egress, and pass-through routing capability. The fabric switch uses a non-blocking crossover switching structure with additional ports provided to allow intermediate result injection. The switch permits the connection of any of the eight ingress ports and five internal result ports to map to any (or all) of the egress ports. This flexibility offers a variety of connection flow topologies and broadcast capabilities among PEs in the tile array. Once a dataflow is configured, high throughput data computation, without need for intermediate storage, can be realized efficiently. Each processing element is designed to allow interception of data samples from any ingress port for its internal computation, as data is flowing through its fabric switch. This technique of synchronized data transfer and on-the-fly computation greatly improves computational throughput and energy efficiency over the conventional load-forward-store architecture which is commonly used in current processor design.

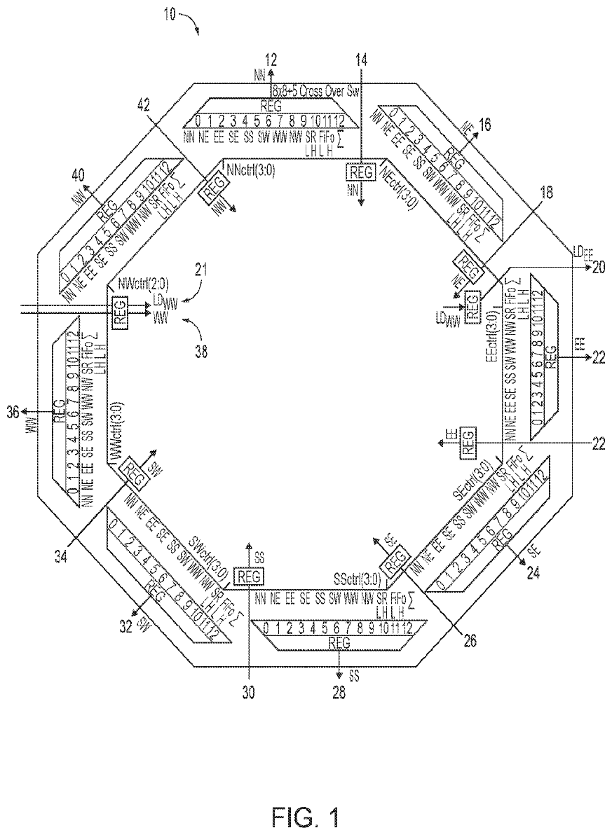

1. Flow-based processing architecture embodiment. As an embodiment, the cWAFER design is a flow-based array processing architecture which employs the memory-less flexible interconnection fabric and “data-on-the-fly” computational model. Each processing element is connected to its neighboring eight processing elements with 40-bit ingress and 40-bit egress buses that can carry 1 data transaction every clock cycle (at 1.5 GHz each cycle is 0.666nS). This yields a maximum throughput rate of 480 Gbps through each PE. The 40-bit port width was selected as a tradeoff between chip area, power, and vector size. Samples in the cWAFER are represented as 20-bit real values or 40-bit complex value pairs. Two ports can be combined to form an 80-bit data flow that can transport a 4-element real vector or a 2-element complex vector. FIG. 1 illustrates 10 the fabric switch structure that provides interface between the processing element computation engine and the network of arrayed processing elements. The interface is provided with ingress data ports 14, 18, 22, 26, 30, 34, 38, and 42, and egress data ports 12, 16, 22, 24, 28, 32, 36, and 40. LDₑₑ (20) and LD_{ww} (21) are additional output and input ports that are provided for loading the PE's. The “LD” Load Data Bus connects adjacent tiles in a row of the tile array.

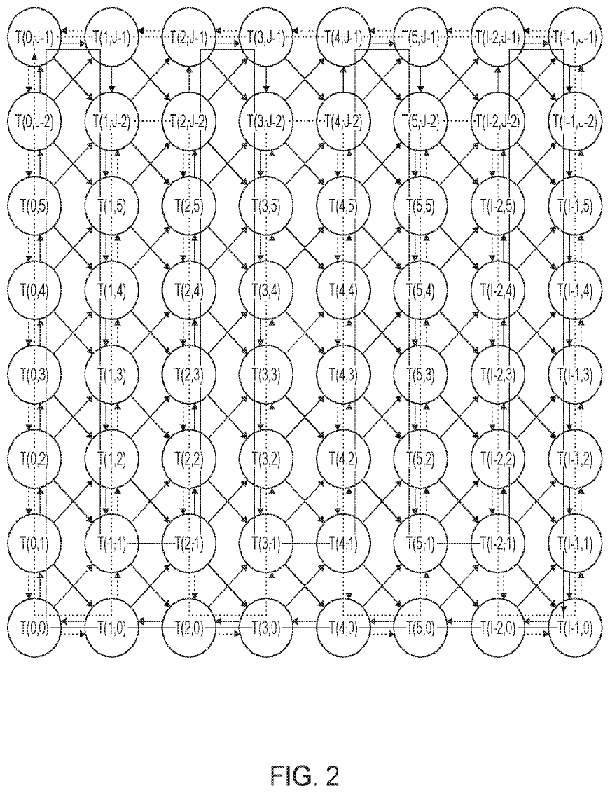

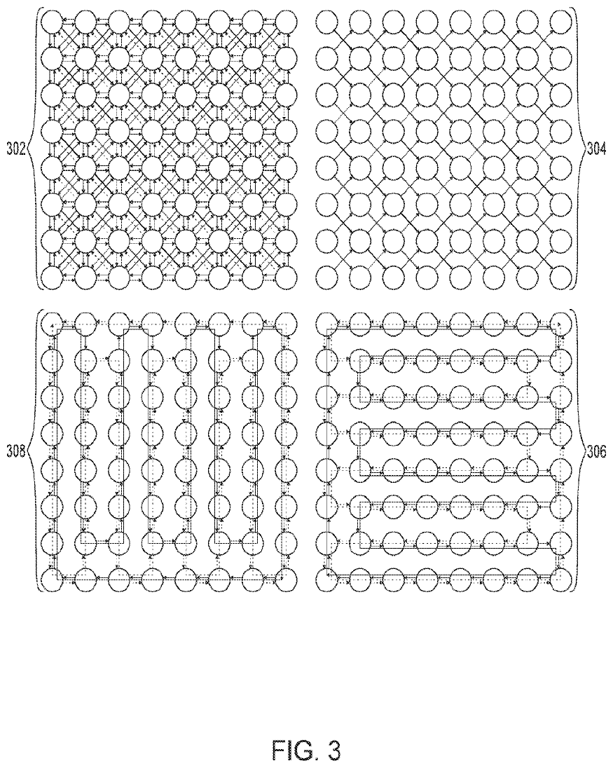

By configuring the fabric switch, one can establish multiple concurrent data flows 200 such as the ones shown in FIG. 2. Similarly, FIG. 3 shows a configurable wafer (cWAFER) array can also be configured to support multiple concurrent workloads, each of which may deploy a different dataflow pattern customized for the workload. FIG. 3 shows four arrays (302, 304, 306, 308), each with a different dataflow pattern.

2. Individually configurable processing elements utilize a long configuration register. Most existing processor designs have a fixed instruction set and execution behavior. The examples described herein include a novel long configuration register (LCR). This LCR can be set independently to alter the internal structure and execution behavior of a PE. The LCR is a single long word register that can be used to (i) change number system representation, (ii) modify program instruction behavior, (iii) define IO flow connections, (iv) provide custom values for indirect operators, and (v) customize functionality of calculation blocks. This introduces a wealth of flexibility while providing a mechanism to reduce program instruction complexity and hardware resources. The configuration register is meant to be set prior to program execution and used to keep the behavior of a PE tile consistent during operation. The architecture also provides a mechanism to update the configuration register settings during execution which produces programming adaptability and allows an algorithm to be adapted during execution. The LCR has impact on the functionality of dynamically controlled operations by redefining behavior of the micro-coded program instructions.

The configuration register is used to control the operating environment for many of the functional blocks within the processing element. As such there are many bits that are needed to set the conditions. The long configuration register is almost 400-bits wide. This is very long especially when compared to the program memory which is only 10-bits wide.

The LCR provides the ability to create a heterogeneous network of processing elements, each of which may have a different execution behavior. Coupling with programmability in each PE, such a heterogeneous network of PEs extends beyond a typical Multiple Instruction Multiple Data (MIMD) class parallel structure.

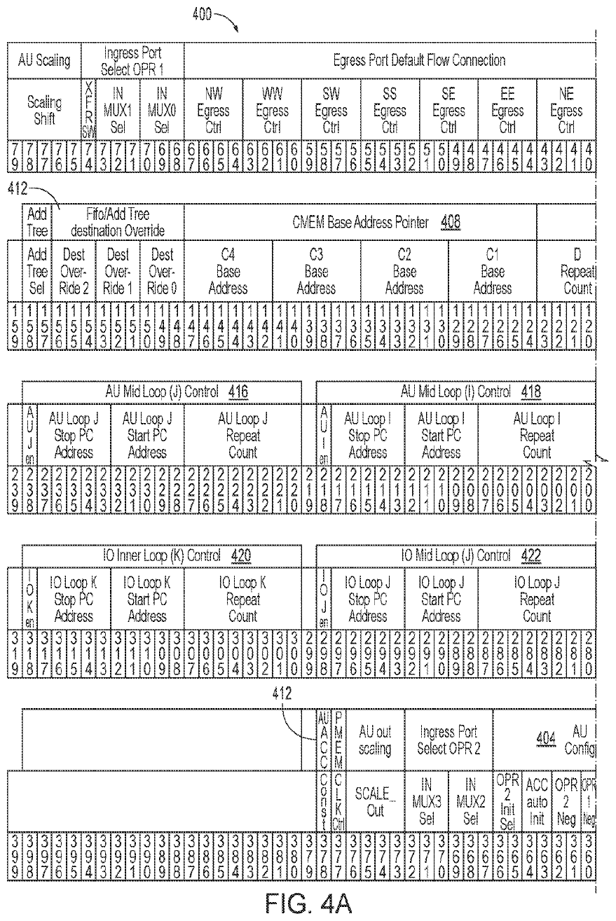

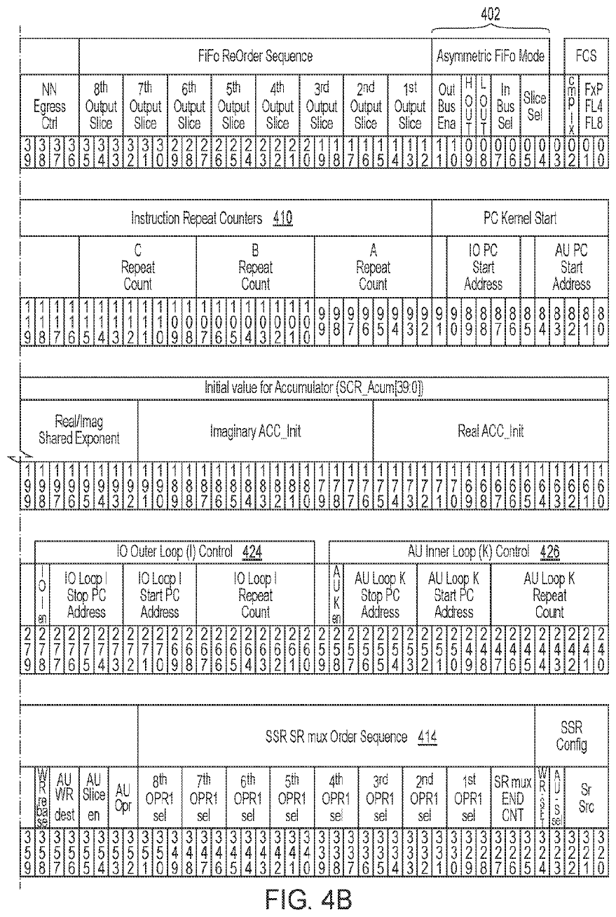

Long configuration register embodiment. In an embodiment shown in FIG. 4, each PE in the cWAFER design has a 378-bit long configuration register 400 that is uniquely defined to alter the functionality of a processing element.

LCR 400 is used to select the number format representation (real or complex, fixed-point or floating-point), and to configure the processing blocks within the PE (asymmetric FiFo (refer to 402), IO ports, scaling, vector arithmetic unit (404, 406), and Sample Shift Register). LCR 400 is also used to define indirect values for address and counter control (408, 410), pointers for FiFo (412) and SSR order sequencing (414). The use of the indirect values in this architecture allows for smaller instruction words (each cWAFER instruction occupies only 10-bits) which greatly reduces the program memory requirements, thereby saving both power and chip area. The LCR 400 also includes bit fields that control the pre-defined nested looping program structure (416, 418, 420, 422, 424, 426) that further reduces program memory size and simplifies instruction set. Considerable attention has been given towards minimizing the memory footprint for the examples described herein with the goal of reducing power consumption and logic count without negatively impacting performance.

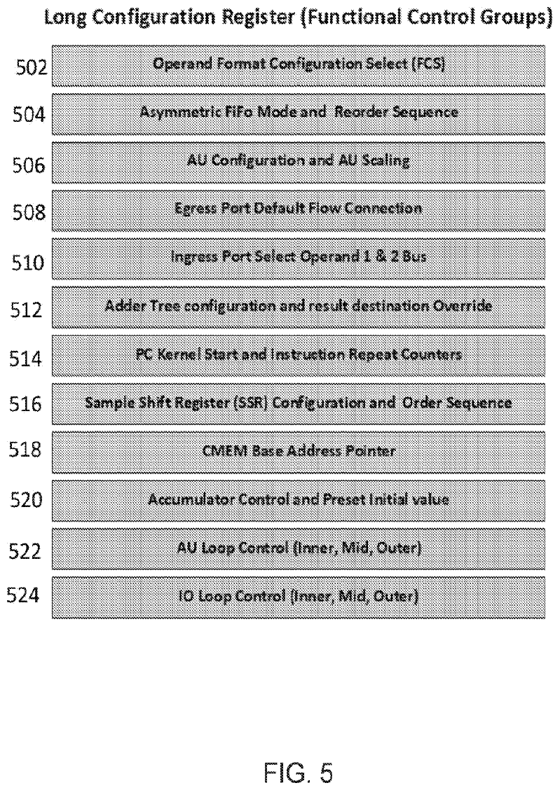

FIG. 5 shows functional control groups of the long configuration register, including operand format configuration select (FCS) 502, asymmetric FIFO mode and reorder sequence 504, AU configuration and AU scaling 506, egress port default flow connection 508, ingress port select operand 1 and 2 bus 510, adder tree configuration and result destination override 512, PC kernel start and instruction repeat counters 514, sample shift register (SSR) configuration and order sequence 516, CMEM base address pointer 518, accumulator control and present initial value 520, AU loop control (inner, mid, outer) 522, and IO loop control (inner, mid, outer) 524.

3. Dual Instruction Flow. The herein described examples incorporate a dual instruction flow that enables the control of compute engine and IO transfers to be concurrent and independent within a PE. A major limitation in early processor design, such as the reduced instruction set computer (RISC), is its single instruction flow in which only one functional unit can be asserted or controlled by an instruction. Most recent designs incorporate a complex instruction set to control multiple functional units, but they greatly expand the size of the instruction set thereby complicating instruction decoding. Other recent processor designs combine multiple instructions into a very long instruction word (VLIW). A VLIW processor thus allows programs to explicitly specify instruction segments to execute in parallel. However, the VLIW design suffers from large program storage and programming or compiler complexity. The dual instruction flow described herein enables higher computational performance without the complexity inherent from these prior designs. It is achieved by allowing the IO unit and compute engine to be controlled independently and concurrently. By synchronizing the I/O with computation results, a program can avoid the impact of delays associated with computational result output to egress ports from stalling the operation pipeline. The dual instruction flow also yields an efficient and compact program storage and simple instruction decoding logic.

To ease programming and aid synchronization between the compute and IO unit within a PE and among PE tiles, the examples described herein feature an instruction set with deterministic timing and control flow. The absence of branch and condition instructions enables an efficient and simple implementation of operational pipeline and control as there is no need for complex branch prediction or predication logic. To retain high programmability, the system employs a pre-defined nested loop program construct specifically designed for signal processing and vector/matrix applications.

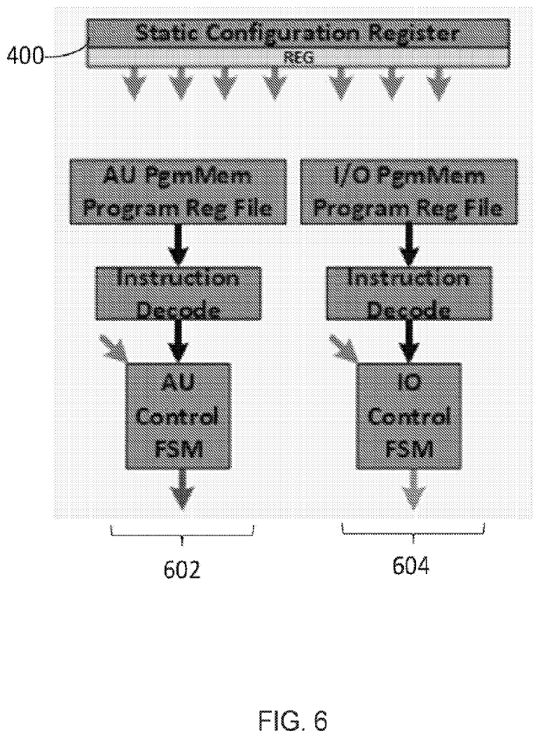

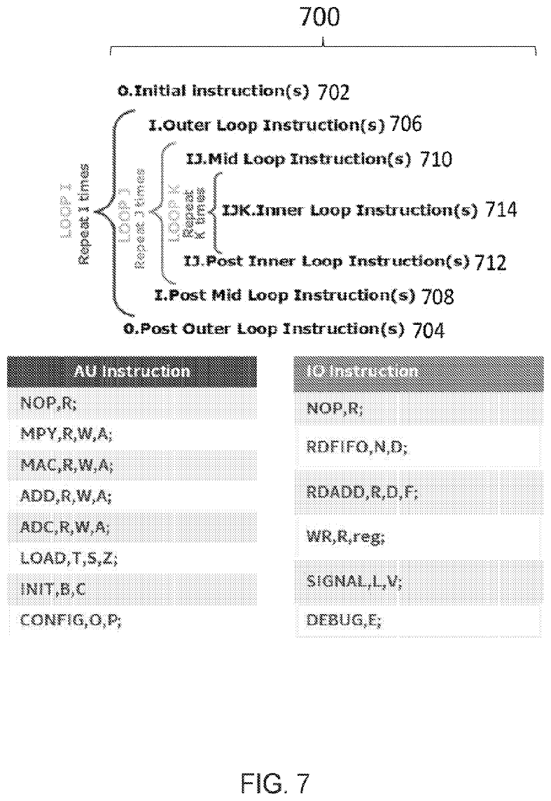

3. Dual Instruction Flow embodiment. FIG. 6 shows an embodiment of the dual instruction flow implementation, with an instruction flow 602 for AU instructions and an instruction flow 604 for IO instructions. FIG. 7 illustrates the pre-defined program construct and the full instruction set realized in cWAFER. The presented program construct is a four-tier nested loop structure. At the first level of looping (702, 704), selected AU and IO instructions are equipped with intrinsic repetition count. On top of this individual instruction-level repetition, the program construct features a 3-level nested looping structure. Loop count at each level (including those given by items 702, 704, 706, 708, 710, 712, and 714) is configurable by fields in the long configuration register. The four-tier nested loop structure 700 includes one or more initial instructions 702, one or more post outer loop instructions 704, one or more outer loop instructions 706, one or more post mid loop instructions 708, one or more mid loop instructions 710, one or more post inner loop instructions 712, and one or more inner loop instructions 714.

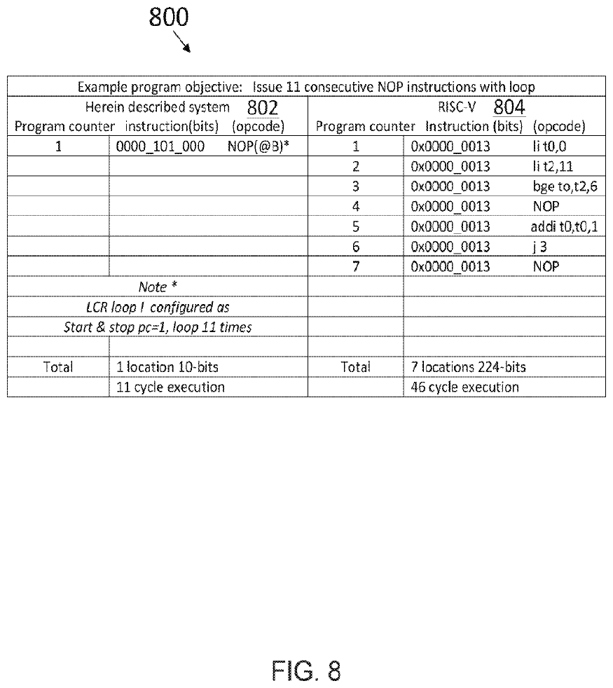

With this pre-defined construct 700, the resulting code size becomes very compact. This enables an efficient hardware implementation. As an example, the table 800 in FIG. 8 shows how the herein described system (802) compares with a RISC ISA (804) in code size and execution time. As can be seen from the table 800 in FIG. 8, the herein described system takes a total of 1 location with 10 bits, with an 11 cycle execution, and RISC-V 804 takes a total of 7 locations with 224 bits, with a 46 cycle execution.

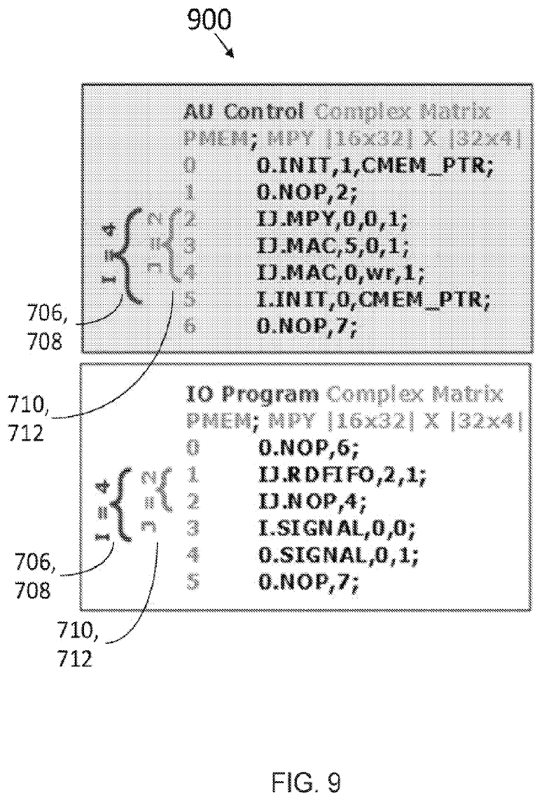

As illustrated by this simple example (e.g. shown in FIG. 8), the system architecture described herein not only provides compact code size that implies less program memory storage, but it also offers efficient program execution. To further illustrate this important benefit, cWAFER programs are typically 5 to 8 instructions long, and multiple program instances can be stored in Program Memory (PMEM) which provide for a fast and flexible context switch between algorithms to be executed. FIG. 9 shows an example program 900 that performs a matrix multiply between a 16×32 matrix and a 32×4 complex matrices.

This program example 900 uses two of the 3 available nested loops (loop K level (714) is disabled), namely those corresponding to 706, 708, 710, and 712. The calculation program uses a Multiply followed by 7 multiply accumulate instructions to calculate 8 rows×1 column of the resultant 16×4 matrix. The J-loop cycles two times to calculate the first 8 rows followed by the next 8 rows. The I-loop cycles 4 times to calculate each of the 4 columns of the result. The AU control program illustrates how the nested loop structure enables multiply instructions to be executed in a continuous series of pipelined instructions without any conditional branch instruction. This allows continuous processing of the data samples without incurring a pipeline stall which greatly improves processor performance.

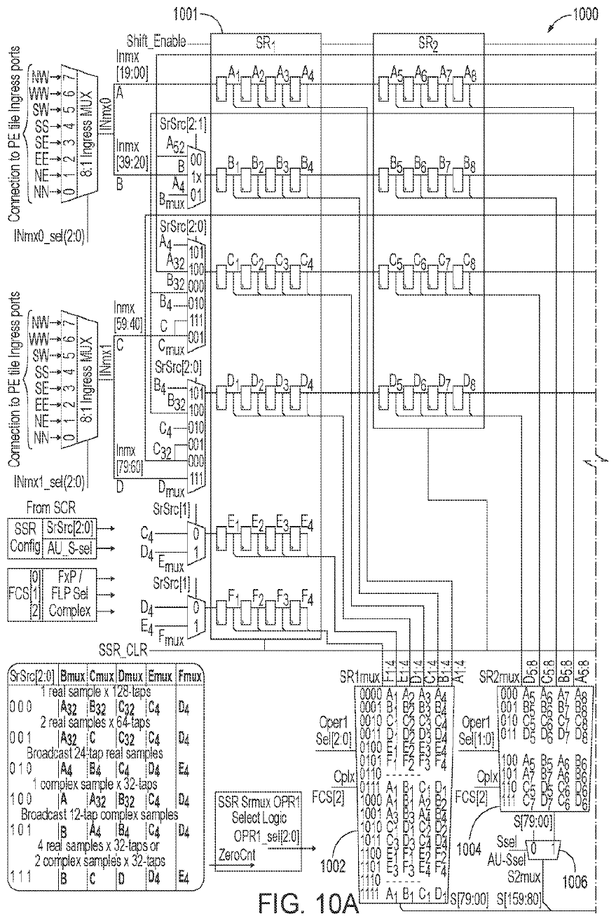

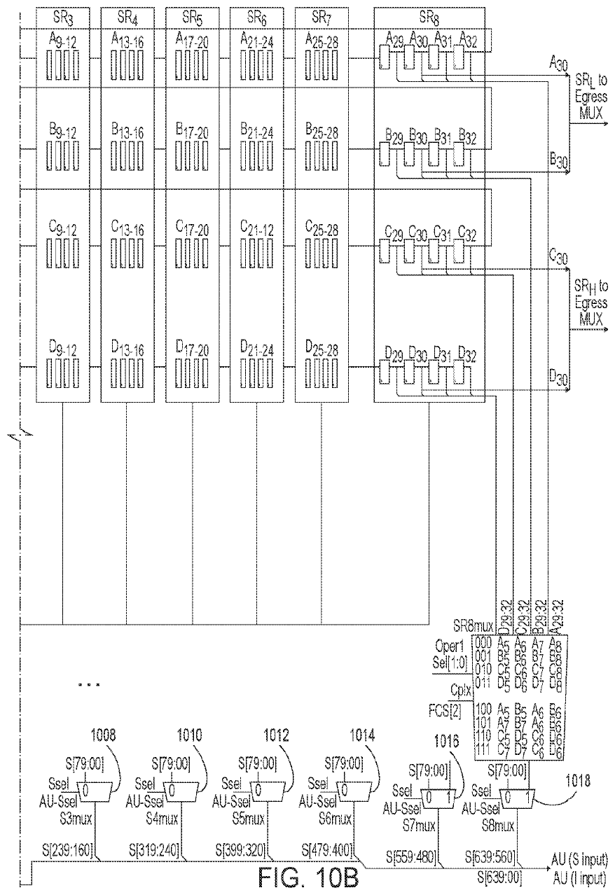

4. A highly configurable sample shift register structure. Besides linear algebraic computations, signal processing algorithms in 5G and 6G (Layer 1, Layer 2, and DFE) often employ heavy usage of correlation, convolution and covariance operation, e.g. finite impulse response (FIR) filter structures, signal detection, etc. A common hardware practice to implement these operations is a set of dedicated delay lines with discrete multiplier and adder tree structures. While this approach exploits parallelism efficiently, it often results in rigid implementations. Other approaches realize these operations in a kernel program using memory or register banks and vector arithmetic instructions. Such implementations provide flexibility, with a performance penalty and high-power consumption. The configurable sample shift register (SSR) structure and corresponding architecture described herein strikes a balance between a hardware and software implementation for these operations. The SSR structure provides a reconfigurable delay line structure that can be used to realize a vast set of configurations. This structure supports both real-value or complex-value data samples for single or multiple channel operations with varying lengths within each processing element. The SSR can also be extended across multiple PE tiles to implement very long structures. Referring to FIG. 10, the SSR 1000 utilizes multiplexers (1002, 1004, 1006, 1008, 1010, 1012, 1014, 1016, 1018) to route segments of the delayed samples to the compute engine providing operands for FIR and correlation applications. The configuration of the SSR structure and the sequencing of the operand multiplexer are set via the long configuration register which defines the PE behavior for a selected algorithm implementation. Configuring the behavior of a processing element statically removes the complexity and performance impacts associated with software implementations.

The shift register structure is used to buffer input samples for FIR filters and correlation filter applications. The shift register holds the input sample operands and can shift those samples to implement delay functions that are necessary in implementing those filters.

4. SSR embodiment. The Sample Shift Register (SSR) structure in the cWAFER design supports both complex value and real value operation for various length configurations. FIG. 10 illustrates the structure of this critical block 1000, which includes SR 1001, needed to implement FIR or correlation filters. An SSR 1000 in each PE can be configured to support from 1 to 4 individual filters simultaneously with varying lengths from 6-taps up to 128-taps. Any shorter filters can be realized by setting the corresponding tap coefficient weights to zero, while any long filters can be realized by coupling SSR structures from adjacent PE tiles.

As examples, the table 1100 shown in FIG. 11 itemizes the structures that can be implemented through the corresponding the long configuration register setting 1102.

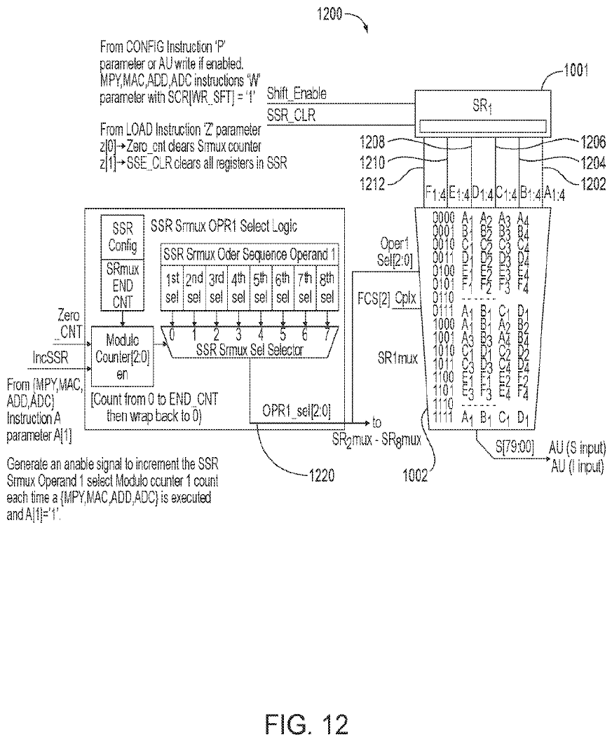

Referring to FIG. 12, this delay line structure is configurable by changing connection paths at the input of six separable horizontal delay segments (1202, 1204, 1206, 1208, 1210, 1212) and by selecting the filter taps from vertical segments that are to be passed as operands to the vector Arithmetic Unit (AU). FIG. 12 shows the control sequencer 1200 that is configured through the LCR, it uses cues from executed instructions to increment pointers and drive the select control for the operand 1 input 1220 to the AU compute engine.

5. A highly configurable and programmable vector/matrix arithmetic unit coupled with an adder tree and asymmetric FIFO. A component of the herein described system architecture is the versatile compute unit inside a PE. The compute unit is composed of a vector arithmetic unit (AU), an adder tree and an asymmetric FIFO. Besides basic vector arithmetic operations, such as addition, accumulation, multiply, and the multiply-accumulate operation, a compute unit can also perform compound operations, e.g., dot product, partial product and element-wise arithmetic operations with a configurable output data order. In a conventional CPU design, an execution unit is controlled solely by an instruction. Conventionally, there would be two unique sets of instructions to govern operations performed by different execution units (e.g. a floating-point AU and a vector AU). Introduced with the examples described herein is the LCR (e.g. 400) which allows a user to pre-configure a compute unit before a program is executed. In other words, the computation results and behavior of the same program may differ depending on the configuration settings in the LCR. For example, an addition instruction in a program can be configured to perform either fixed-point or floating-point add on one or more vector operands whose values can be represented as real or complex numbers. As the hardware realization of a complex arithmetic unit generally requires more than twice the circuitry of a real arithmetic unit, a complex compute unit in a conventional CPU consumes significantly more power than a simple one. This is because in a conventional CPU design, both type of AU's are kept active most of the time since the hardware control has no prior information about which type of instruction will be executed. In the design described herein, in contrast, this a priori information about an application is given through the LCR configuration. More aggregative power control and energy saving techniques can therefore be applied on the functional units without affecting the overall computation performance. Several power control techniques such as clock gating, deep sleep mode and power gating are incorporated in the compute unit to shutdown idling or unused circuitry.

The asymmetric FIFO is referred to as being asymmetric because it simultaneously can capture the results from all slices of the vector arithmetic unit and then can selectively output a selected subset of the results captured. In the cWAFER embodiment the asymmetric FIFO collects a 640-bit input word in 1 clock cycle—it can output 40-bits (or 80-bit) words every clock cycle. This is the asymmetric nature of this block, using 1 clock to write 640-bits and up to 16 clocks to read the FIFO values. A symmetric FIFO would be used to clock in words and clock out words that are the same bit width.

Considering commonly used signal processing algorithms and applications, operations such as operand negation, conjugation, complex conjugation, operand data format and compound operations can be set via configuration, while basic operations such as addition, accumulation, multiply, and multiply accumulate operations remain programmable. The combination of configurability and programmability offer an opportunity to realize a versatile compute unit with high energy efficiency, while maintaining the flexibility of its architecture.

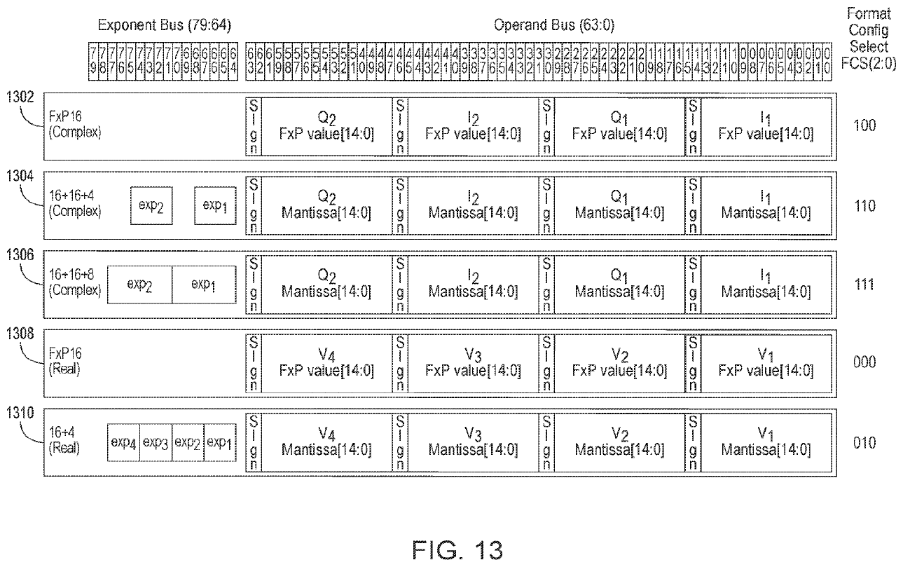

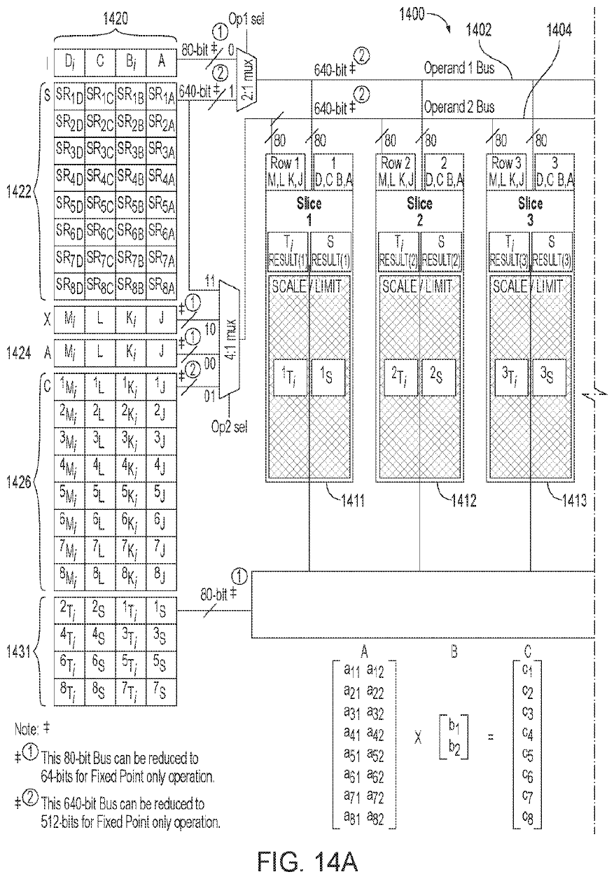

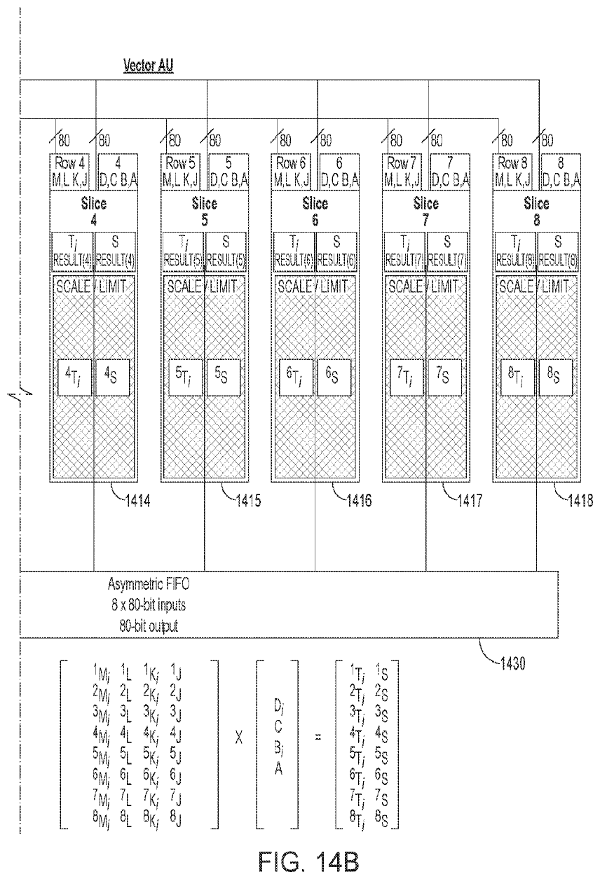

5. Embodiment of the highly configurable and programmable vector/matrix arithmetic unit coupled with an adder tree and asymmetric FIFO. As an embodiment, the compute engine realized in the cWAFER supports as many as five different data formats (1302, 1304, 1306, 1308, 1310) as depicted in FIG. 13. The arithmetic unit inside a compute unit is therefore designed to interpret operands in various formats and perform an operation accordingly. FIG. 14 shows a block diagram 1400 of the vector AU, the operand 1 and operand 2 buses (1402 and 1404, respectively) provide 80-bit vector segments into each of the 8 slices (1411, 1412, 1413, 1414, 1415, 1416, 1417, 1418). The source of operand data is configured via the LCR and can be programmed (AU or IO instruction) dynamically to source from Ingress ports 1420, the Sample Shift Register (SSR) 1422, operand register A 1424, or the coefficient memory (CMEM) 1426. Combining the vector operations performed in each AU slice and a configuration of asymmetric FIFO 1430, a compute unit can produce the desired matrix arithmetic results in a specific output order. The asymmetric FIFO 1430 provides outputs as block 1431.

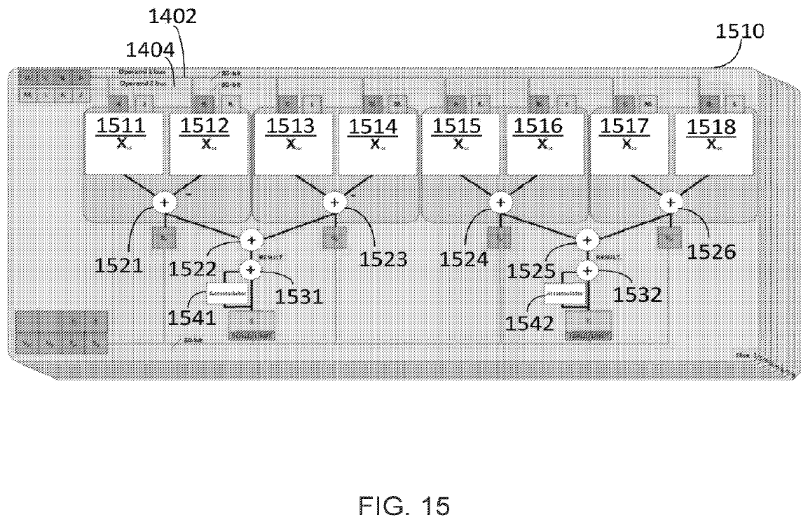

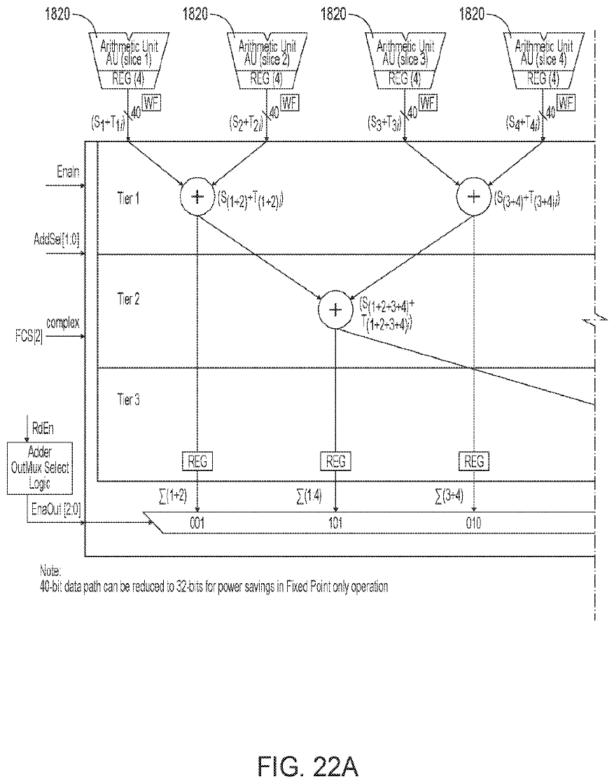

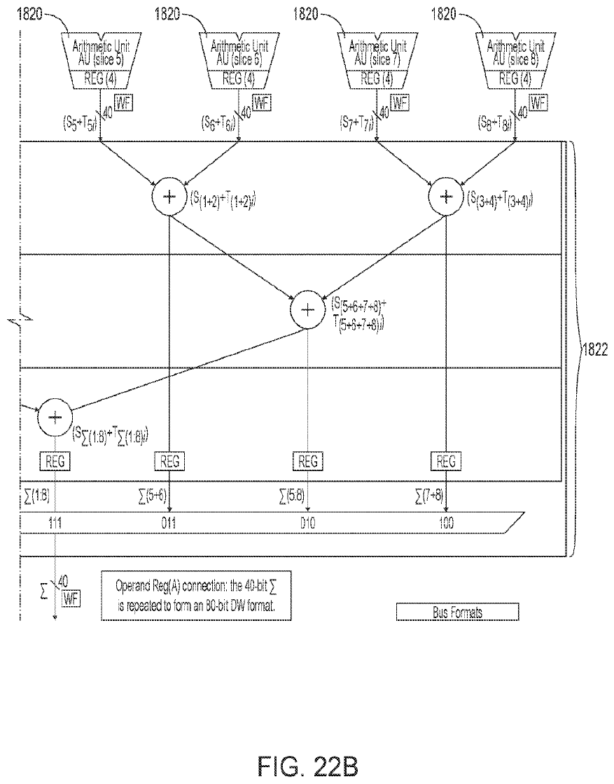

FIG. 15 shows a block diagram for one (1510) of eight identical vector AU slices. Each slice has 8 multifunction add/multiply blocks (1511, 1512, 1513, 1514, 1515, 1516, 1517, 1518) that combined with 6 adder blocks (1521, 1522, 1523, 1524, 1525, 1526) perform complex arithmetic multiplies (or adds) on 2 complex element vectors. Two additional adders (1531, 1532) coupled with an accumulation register (1541, 1542) extend the processing capability to include multiply-accumulate (MAC) and add-accumulate (ADC) functions. In total, each vector AU has a total of 64 multipliers and 64 adders. A compute unit also has an additional 14 adders in the adder tree unit (1822 of FIG. 22) that can perform a summation of the results from all 8 AU slices. All these multipliers and adders can support fixed and floating-point operation and are configurable via LCR 400.

The cWAFER implementation is an embodiment of the examples described herein including all features mentioned herein. FIG. 16 shows a top-level block diagram 1600 of the cWAFER subsystem, including cWAFER accelerator subsystem 1601. In addition to the cWAFER core PE array 1602, the subsystem includes a small RISC-V processor 1604 for housekeeping tasks and to serve as a control interface intermediary between the host system and the cWAFER array processor (core) 1608. To simplify integration into different host systems, connection to the cWAFER accelerator 1601 is loosely coupled through a system interface memory (SIM) 1610 that stores configuration, control requests, and data samples. Within a cWAFER array (e.g. 1602), all processing elements (PE) (e.g. 10) and IO elements (tiles) (1614, 1616) operate with a tightly coupled timing and data relationship for high processing throughput. The combination of a loosely coupled interface at the subsystem level 1601 and tightly coupled interface at the core level 1620 presents a well-balanced tradeoff between performance and flexibility.

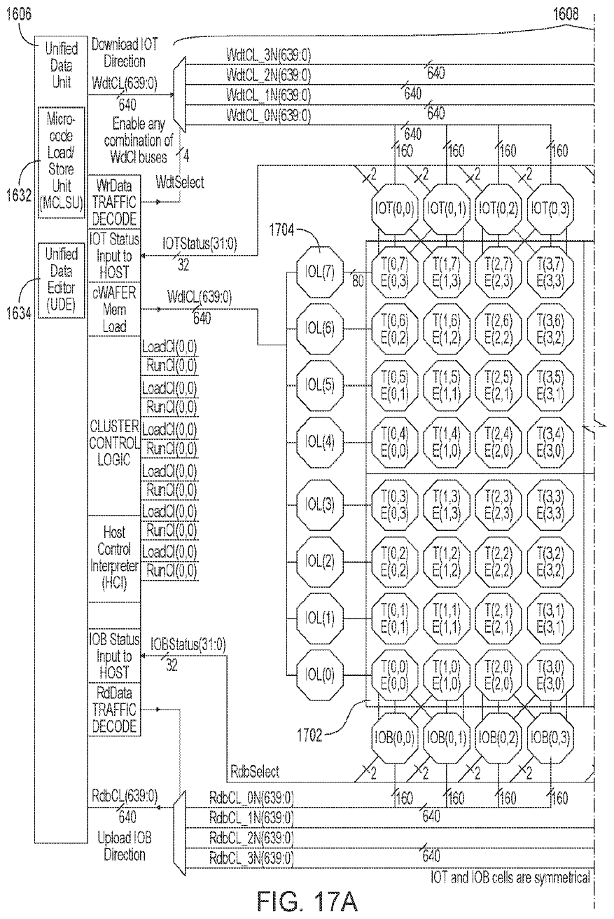

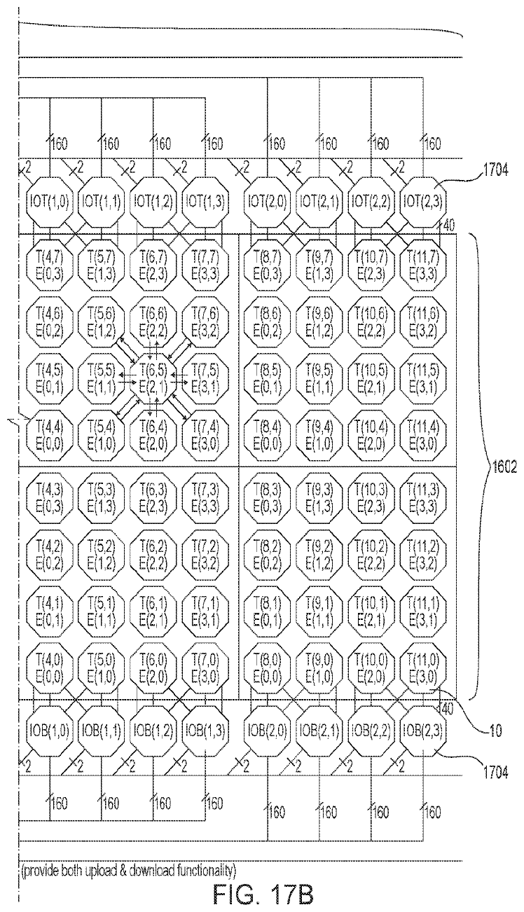

FIG. 17 illustrates in more detail the cWAFER array processor (core) 1608 and its interface to the unified data unit (UDU) 1606. The UDU 1606 facilitates transfer of data samples or results between the PE array 1602 and the SIM 1610. cWAFER array 1602 is a scalable design in which the number of processing elements 10 can be customized to the target set of applications. The basic building block is a cluster 1702 (16 PE tiles 10) arranged as an array of 4×4. A cluster 1702 share common control and status signaling to the host interface, while each of the 16 PE 10 maintain their own unique configuration and program. FIG. 17 illustrates a 6-cluster example arranged as an 8 row by 12 column array 1602.

The UDU 1606 connects the array processor block 1608 to the streaming data memory (SDM) 1622 that buffers user plane data samples 1624 and computation results 1626. The UDU 1606 also links the load data memory (LDM) 1628, which hold configuration and program images 1630, to the array processor 1608. The microcoded load store unit (MCLSU) 1632 generates address pointers for up to 8 individual data streams (4 for data samples and 4 for result upload) to the SDM 1622 and 1 address generator for interface to the LDM 1628. This reference structure provides the necessary flexibility for 4 simultaneous functions to run independently. The UDU 1606 includes an additional feature in unified data editor (UDE) 1634 that reorders or shuffles the input data samples and converts their format on-the-fly before transfer in/out of the array 1602.

Data transfer in and out of the cWAFER array 1602 is mediated through the IO Elements (tiles) 1704 that are placed on the top and bottom of the array 1602. These IO tiles 1704 contain FIFO memory to ease clock domain crossing. To maintain high computational performance, the cWAFER array 1602 typically operates at a higher clock frequency than the rest of the subsystem 1601 and the host system.

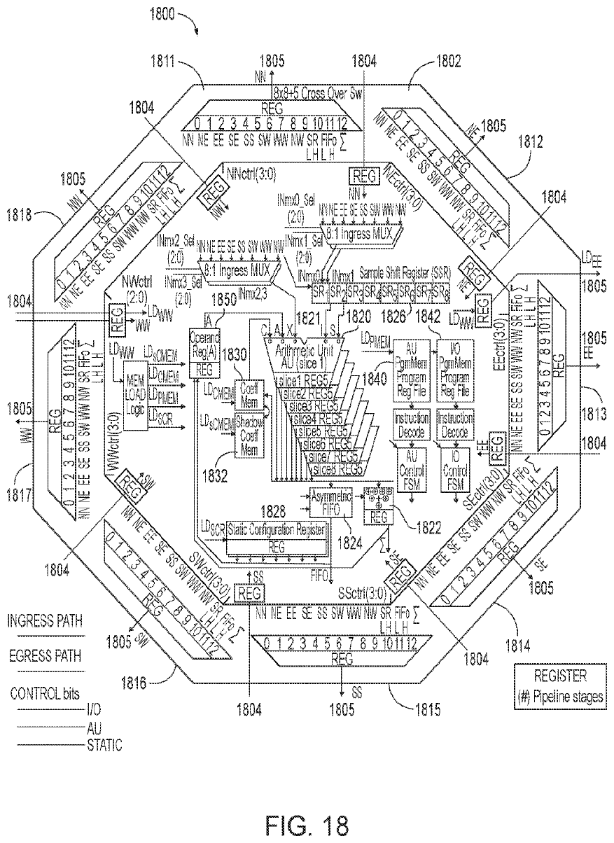

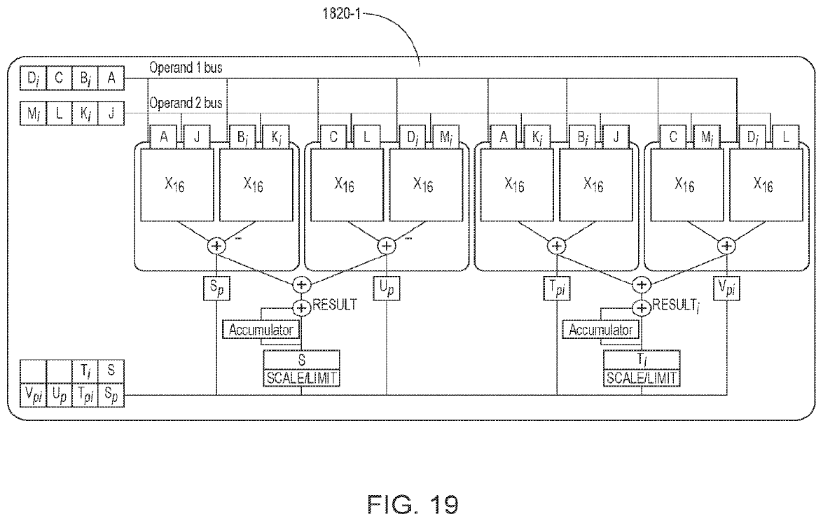

FIG. 18 provides a detailed view of a cWAFER processing element 1800 (also 10, as components of the processing element 1800 have also been described previously). Around its perimeter is an 8×8+5 fabric interconnect switch 1802 that is used to connect with the array interconnect fabric. Through the Ingress port inputs 1804, from its 8 adjacent tiles {North 1811, North-East 1812, East 1813, South-East 1814, South 1815, South-West 1816, West 1817, and NorthWest 1818}, data is simultaneously made available to the compute unit (including slice 1820 of the AU, which slice 1820 is similar to item 1510). The compute unit may directly output its results to any or all of its 8 egress ports 1805. Or it can be configured to (i) route the intermediate results through the adder tree 1822 before outputting, (ii) temporarily store the intermediate results in the Asymmetric FIFO 1824 for reformatting or reordering; or (iii) store the intermediate results in the Coefficient Memory 1830 or the Operand Register(A) 1850. A novelty of this architecture is the ability for a tile program to inject its calculated results into the configured flow connection thereby temporarily overriding pass-thru data to forward those results. Selection of an egress source towards the fabric interconnect switch 1802 is set through the long configuration register (LCR) 1828 (refer also to 400) and can be modified by program control.

The use of a long configuration register 1828 alters the operating behavior within a PE tile 1800 and enables a program to be adapted easily. The long configuration register 1828 is generally loaded before program execution, but it can also be modified dynamically during execution. The following is a list of parameters and functions configurable via LCR settings: i) number system selection (complex or real, fixed or floating-point) for computation, ii) functional block configurations, iii) hardware nested loop control parameters, iv) default ingress egress connections, v) indirect parameters for program reference.

The cWAFER array 1602 is architected for a flow-based computation which greatly reduces intermediate data storage and memory access thereby significantly improving computational performance and energy efficiency over conventional multicore processor designs. Data parallelism in an algorithm can be exploited and realized by using a single PE (8 AU slices) or a combination of multiple PEs 1800. The architecture is therefore scalable with minimal overhead.

The cWAFER array 1602 also adopts the concept of near memory computing in which a small private memory is placed next to the compute unit, to reduce the overhead, latency and power consumption of accessing the frequently used reference data, such as precoding coefficients, beamforming weights, FEQ coefficients, etc. Each PE tile 1800 has a coefficient memory (CMEM) 1830 and its alternate storage, called shadow CMEM 1832 that can be used as auxiliary operands. The CMEM 1830 can simultaneously supply 8 vectors of 4 real values (or 2 complex pair) to the vector arithmetic unit 1821. The CMEM 1830 and its shadow 1832 operate in a ping-pong fashion to allow external loading of the standby copy while the active copy is in operation. Shown also in FIG. 18 is the dual instruction flow for AU transfers (1840) and IO transfers (1842). Refer also to FIG. 6 (items 602 and 604).

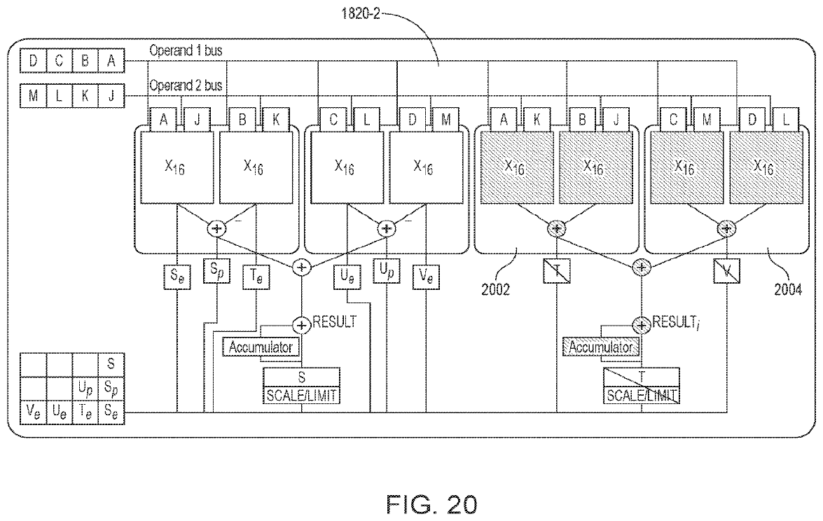

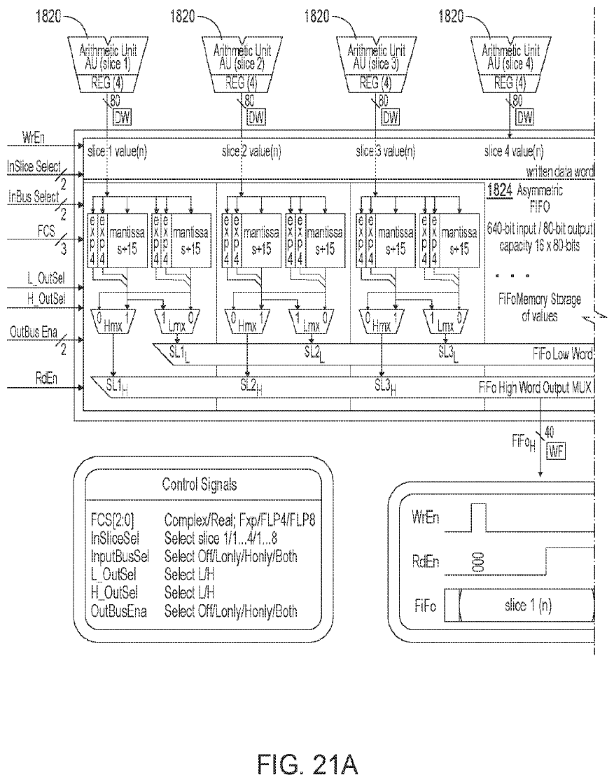

Each cWAFER compute unit includes a configurable vector arithmetic unit 1821, an adder tree 1822 and an asymmetric FIFO unit 1824. There are 8 identical AU Slices 1820 in each PE 1800. Each slice 1820 can multiply a 4-element real vector with another 4-element real vector every clock cycle (plus pipeline overhead). The AU Slice 1820 can also be configured to perform operations on vectors of 2 complex pair elements with the same throughput. Depending on an application, selected features of an AU slice 1820 or the entire slice can be placed in an energy saving mode to reduce power consumption. FIG. 19 and FIG. 20 illustrate a vector arithmetic unit slice (1820-1, 1820-2) configured for complex (item 1821-1) and real operation (item 1821-2), respectively. Blocks 2002 and 2004 are placed in a low power state since they are not needed for real value computation.

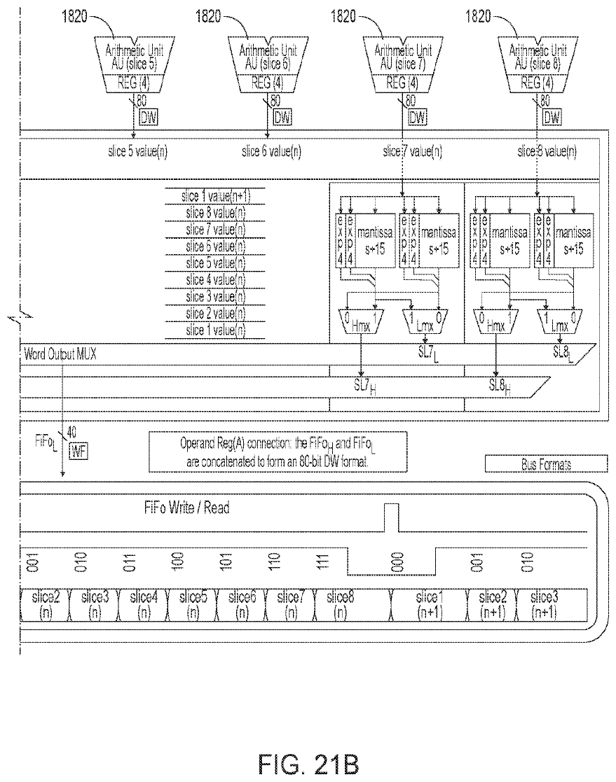

Referring to FIG. 21, the asymmetric FIFO unit 1824 (similarly 1430 of FIG. 14) is designed to instantaneously capture results from all 8 AU Slices 1820 and to provide temporary storage pending for transfer programmed via IO instructions. The asymmetric FIFO unit 1824 can also be configured to reorder the results from each of the slices 1820 matching with the target algorithm or dataflow.

Referring to FIG. 22, the adder tree 1822 in a compute unit is used for operations that require the independent results from the 8 AU slices 1820 to be combined. The unit 1822 can be configured to produce a single sum of all 8 slice results, or 2 sums of 4 slice results, or 4 sums of 2 slice results. Output of the adder tree sums are controlled via the IO instructions.

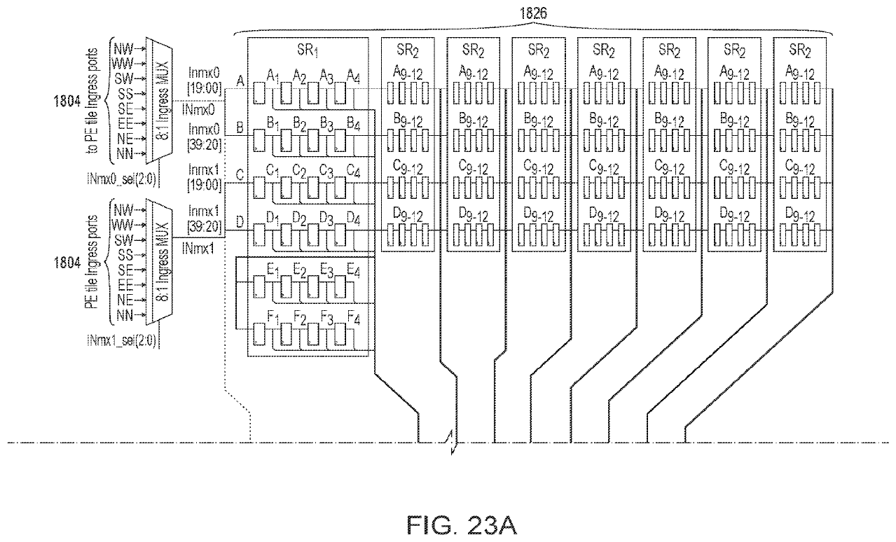

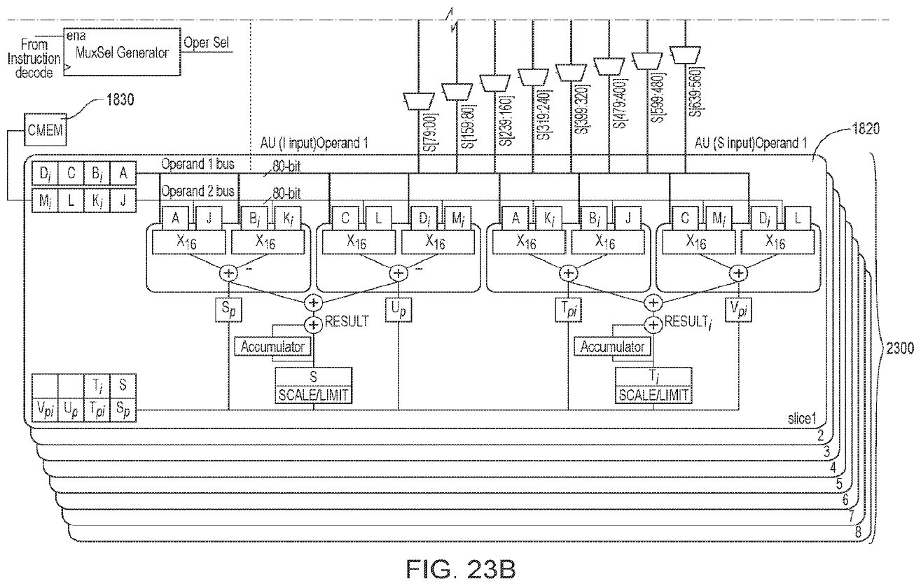

FIG. 23 illustrates the SSR 1826 (refer also to 1000) and its connection to the calculation engine 230-0 including slices 1820. Coupling with the compute unit 2300 is a sample shift register (SSR) 1826 structure that is typically used for realizing correlation, convolution and covariance operations. The SSR 1826 can be configured to implement a real or complex-value filter with different lengths. The SSR 1826 can also be configured to support filters with multiple input channels. Configurations listed below can easily be realized using the SSR 1826 and the compute unit 2300:
{Real Filters: 128-tap 1-channel, 64-tap 2-channel, 32-tap 4-channel, 24-tap shared filter}
{Complex Filters: 64-tap 1-channel, 32-tap 2-channel, 12-tap shared filter}

Execution of a cWAFER processing element (1800, 10) is governed by two independent, but synchronized instruction flows: one controls the AU operations (1840, 602) while the other controls IO operation (1842, 604). This split instruction issue approach offers an effective and efficient way to synchronize computation and data/result IO. The cWAFER PE (1800, 10) is designed to be programmed by a pre-defined program construct 700, as depicted in FIG. 7, which eliminates the need for discrete condition and branch instructions. A PE execution is therefore completely deterministic without the need for branch prediction or predication logic. The pre-defined program construct 700 is a 4-level nested loop structure. The first level loop (702, 704) is the self-repetition of an instruction as specified in the Repeat field in the instruction format. Most instructions are defined with a 3-bit field to encode the repeat parameter. This parameter is used by the instruction execution unit to perform the given instruction for additional cycles. This repeat parameter can be used to code 4 direct additional (immediate) repeat values {0,1,2,3} or it can be used to specify an indirect repeat value pointer. The repeat value pointers direct the instruction execution unit to access one of four 8-bit values that are stored in the LCR (400, 1828). Thus, any repeat value of up to 255 can be configured. The 3 remaining levels of nested loop structure (level including 706 and 708, level including 710 and 712, level including 714) use fields specified in the LCR (400, 1828) to define their looping behavior. Using this pre-defined program construct 700 and hardware-assisted loop execution, the instruction set and code size can be significantly reduced. It results in compact program storage, efficient program control and execution.

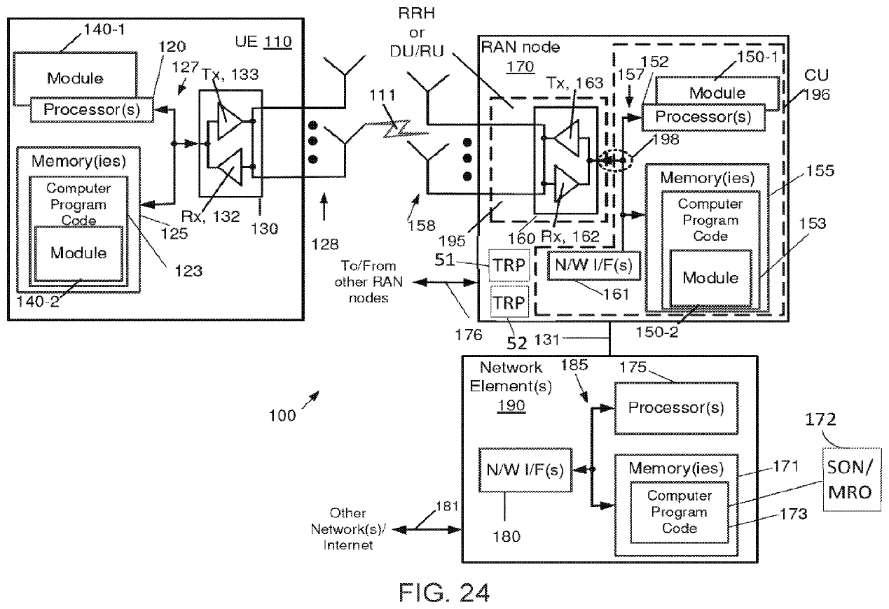

Turning to FIG. 24, this figure shows a block diagram of one possible and non-limiting example in which the examples may be practiced. A user equipment (UE) 110, radio access network (RAN) node 170, and network element(s) 190 are illustrated. In the example of FIG. 24, the user equipment (UE) 110 is in wireless communication with a wireless network 100. A UE is a wireless device that can access the wireless network 100. The UE 110 includes one or more processors 120, one or more memories 125, and one or more transceivers 130 interconnected through one or more buses 127. Each of the one or more transceivers 130 includes a receiver, Rx, 132 and a transmitter, Tx, 133. The one or more buses 127 may be address, data, or control buses, and may include any interconnection mechanism, such as a series of lines on a motherboard or integrated circuit, fiber optics or other optical communication equipment, and the like. The one or more transceivers 130 are connected to one or more antennas 128. The one or more memories 125 include computer program code 123. The UE 110 includes a module 140, comprising one of or both parts 140-1 and/or 140-2, which may be implemented in a number of ways. The module 140 may be implemented in hardware as module 140-1, such as being implemented as part of the one or more processors 120. The module 140-1 may be implemented also as an integrated circuit or through other hardware such as a programmable gate array. In another example, the module 140 may be implemented as module 140-2, which is implemented as computer program code 123 and is executed by the one or more processors 120. For instance, the one or more memories 125 and the computer program code 123 may be configured to, with the one or more processors 120, cause the user equipment 110 to perform one or more of the operations as described herein. The UE 110 communicates with RAN node 170 via a wireless link 111.

The RAN node 170 in this example is a base station that provides access for wireless devices such as the UE 110 to the wireless network 100. The RAN node 170 may be, for example, a base station for 5G, also called New Radio (NR). In 5G, the RAN node 170 may be a NG-RAN node, which is defined as either a gNB or an ng-eNB. A gNB is a node providing NR user plane and control plane protocol terminations towards the UE, and connected via the NG interface (such as connection 131) to a 5GC (such as, for example, the network element(s) 190). The ng-eNB is a node providing E-UTRA user plane and control plane protocol terminations towards the UE, and connected via the NG interface (such as connection 131) to the 5GC. The NG-RAN node may include multiple gNBs, which may also include a central unit (CU) (gNB-CU) 196 and distributed unit(s) (DUs) (gNB-DUs), of which DU 195 is shown. Note that the DU 195 may include or be coupled to and control a radio unit (RU). The gNB-CU 196 is a logical node hosting radio resource control (RRC), SDAP and PDCP protocols of the gNB or RRC and PDCP protocols of the en-gNB that control the operation of one or more gNB-DUs. The gNB-CU 196 terminates the F1 interface connected with the gNB-DU 195. The F1 interface is illustrated as reference 198, although reference 198 also illustrates a link between remote elements of the RAN node 170 and centralized elements of the RAN node 170, such as between the gNB-CU 196 and the gNB-DU 195. The gNB-DU 195 is a logical node hosting RLC, MAC and PHY layers of the gNB or en-gNB, and its operation is partly controlled by gNB-CU 196. One gNB-CU 196 supports one or multiple cells. One cell may be supported with one gNB-DU 195, or one cell may be supported/shared with multiple DUs under RAN sharing. The gNB-DU 195 terminates the F1 interface 198 connected with the gNB-CU 196. Note that the DU 195 is considered to include the transceiver 160, e.g., as part of a RU, but some examples of this may have the transceiver 160 as part of a separate RU, e.g., under control of and connected to the DU 195. The RAN node 170 may also be an eNB (evolved NodeB) base station, for LTE (long term evolution), or any other suitable base station or node.

The RAN node 170 includes one or more processors 152, one or more memories 155, one or more network interfaces (N/W I/F(s)) 161, and one or more transceivers 160 interconnected through one or more buses 157. Each of the one or more transceivers 160 includes a receiver, Rx, 162 and a transmitter, Tx, 163. The one or more transceivers 160 are connected to one or more antennas 158. The one or more memories 155 include computer program code 153. The CU 196 may include the processor(s) 152, memory(ies) 155, and network interfaces 161. Note that the DU 195 may also contain its own memory/memories and processor(s), and/or other hardware, but these are not shown.

The RAN node 170 includes a module 150, comprising one of or both parts 150-1 and/or 150-2, which may be implemented in a number of ways. The module 150 may be implemented in hardware as module 150-1, such as being implemented as part of the one or more processors 152. The module 150-1 may be implemented also as an integrated circuit or through other hardware such as a programmable gate array. In another example, the module 150 may be implemented as module 150-2, which is implemented as computer program code 153 and is executed by the one or more processors 152. For instance, the one or more memories 155 and the computer program code 153 are configured to, with the one or more processors 152, cause the RAN node 170 to perform one or more of the operations as described herein. Note that the functionality of the module 150 may be distributed, such as being distributed between the DU 195 and the CU 196, or be implemented solely in the DU 195.

The one or more network interfaces 161 communicate over a network such as via the links 176 and 131. Two or more gNBs 170 may communicate using, e.g., link 176. The link 176 may be wired or wireless or both and may implement, for example, an Xn interface for 5G, an X2 interface for LTE, or other suitable interface for other standards.

The one or more buses 157 may be address, data, or control buses, and may include any interconnection mechanism, such as a series of lines on a motherboard or integrated circuit, fiber optics or other optical communication equipment, wireless channels, and the like. For example, the one or more transceivers 160 may be implemented as a remote radio head (RRH) 195 for LTE or a distributed unit (DU) 195 for gNB implementation for 5G, with the other elements of the RAN node 170 possibly being physically in a different location from the RRH/DU 195, and the one or more buses 157 could be implemented in part as, for example, fiber optic cable or other suitable network connection to connect the other elements (e.g., a central unit (CU), gNB-CU 196) of the RAN node 170 to the RRH/DU 195. Reference 198 also indicates those suitable network link(s).

A RAN node/gNB can comprise one or more TRPs to which the methods described herein may be applied. FIG. 24 shows that the RAN node 170 comprises two TRPs, TRP 51 and TRP 52. The RAN node 170 may host or comprise other TRPs not shown in FIG. 24.

A relay node in NR is called an integrated access and backhaul node. A mobile termination part of the IAB node facilitates the backhaul (parent link) connection. In other words, it is the functionality which carries UE functionalities. The distributed unit part of the IAB node facilitates the so called access link (child link) connections (i.e. for access link UEs, and backhaul for other IAB nodes, in the case of multi-hop IAB). In other words, it is responsible for certain base station functionalities. The IAB scenario may follow the so called split architecture, where the central unit hosts the higher layer protocols to the UE and terminates the control plane and user plane interfaces to the 5G core network.

It is noted that the description herein indicates that “cells” perform functions, but it should be clear that equipment which forms the cell may perform the functions. The cell makes up part of a base station. That is, there can be multiple cells per base station. For example, there could be three cells for a single carrier frequency and associated bandwidth, each cell covering one-third of a 360 degree area so that the single base station's coverage area covers an approximate oval or circle. Furthermore, each cell can correspond to a single carrier and a base station may use multiple carriers. So if there are three 120 degree cells per carrier and two carriers, then the base station has a total of 6 cells.

The wireless network 100 may include a network element or elements 190 that may include core network functionality, and which provides connectivity via a link or links 181 with a further network, such as a telephone network and/or a data communications network (e.g., the Internet). Such core network functionality for 5G may include location management functions (LMF(s)) and/or access and mobility management function(s) (AMF(S)) and/or user plane functions (UPF(s)) and/or session management function(s) (SMF(s)). Such core network functionality for LTE may include MME (Mobility Management Entity)/SGW (Serving Gateway) functionality. Such core network functionality may include SON (self-organizing/optimizing network) functionality. These are merely example functions that may be supported by the network element(s) 190, and note that both 5G and LTE functions might be supported. The RAN node 170 is coupled via a link 131 to the network element 190. The link 131 may be implemented as, e.g., an NG interface for 5G, or an S1 interface for LTE, or other suitable interface for other standards. The network element 190 includes one or more processors 175, one or more memories 171, and one or more network interfaces (N/W I/F(s)) 180, interconnected through one or more buses 185. The one or more memories 171 include computer program code 173. Computer program code 173 may include SON and/or MRO functionality 172.

The wireless network 100 may implement network virtualization, which is the process of combining hardware and software network resources and network functionality into a single, software-based administrative entity, a virtual network. Network virtualization involves platform virtualization, often combined with resource virtualization. Network virtualization is categorized as either external, combining many networks, or parts of networks, into a virtual unit, or internal, providing network-like functionality to software containers on a single system. Note that the virtualized entities that result from the network virtualization are still implemented, at some level, using hardware such as processors 152 or 175 and memories 155 and 171, and also such virtualized entities create technical effects.

The computer readable memories 125, 155, and 171 may be of any type suitable to the local technical environment and may be implemented using any suitable data storage technology, such as semiconductor based memory devices, flash memory, magnetic memory devices and systems, optical memory devices and systems, non-transitory memory, transitory memory, fixed memory and removable memory. The computer readable memories 125, 155, and 171 may be means for performing storage functions. The processors 120, 152, and 175 may be of any type suitable to the local technical environment, and may include one or more of general purpose computers, special purpose computers, microprocessors, digital signal processors (DSPs) and processors based on a multi-core processor architecture, as non-limiting examples. The processors 120, 152, and 175 may be means for performing functions, such as controlling the UE 110, RAN node 170, network element(s) 190, and other functions as described herein.

In general, the various example embodiments of the user equipment 110 can include, but are not limited to, cellular telephones such as smart phones, tablets, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, tablets with wireless communication capabilities, head mounted displays such as those that implement virtual/augmented/mixed reality, as well as portable units or terminals that incorporate combinations of such functions. The UE 110 can also be a vehicle such as a car, or a UE mounted in a vehicle, a UAV such as e.g. a drone, or a UE mounted in a UAV.

UE 110, RAN node 170, and/or network element(s) 190, (and associated memories, computer program code and modules) may be configured to implement (e.g. in part) the methods described herein, including a configurable wavefront parallel processor. Thus, computer program code 123, module 140-1, module 140-2, and other elements/features shown in FIG. 24 of UE 110 may implement user equipment related aspects of the examples described herein. Similarly, computer program code 153, module 150-1, module 150-2, and other elements/features shown in FIG. 24 of RAN node 170 may implement gNB/TRP related aspects of the examples described herein. Computer program code 173 and other elements/features shown in FIG. 24 of network element(s) 190 may be configured to implement network element related aspects of the examples described herein.

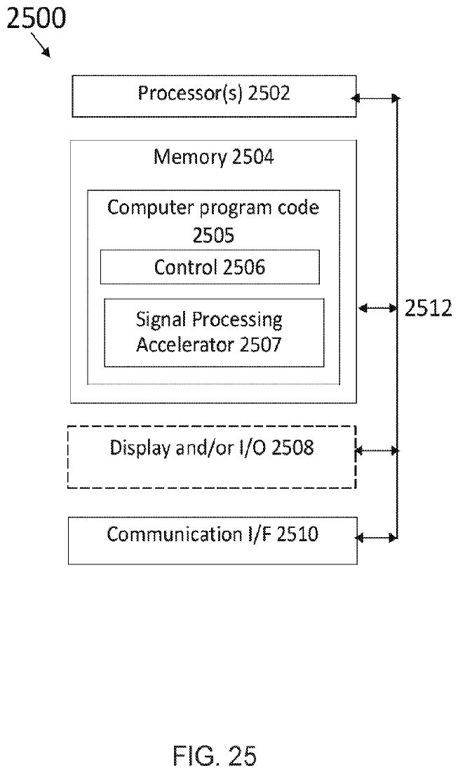

FIG. 25 is an example apparatus 2500, which may be implemented in hardware, configured to implement the examples described herein. The apparatus 2500 comprises at least one processor 2502 (e.g. an FPGA and/or CPU), at least one memory 2504 including computer program code 2505, wherein the at least one memory 2504 and the computer program code 2505 are configured to, with the at least one processor 2502, cause the apparatus 2500 to implement circuitry, a process, component, module, or function (collectively control 2506 and/or signal processing accelerator 2507) to implement the examples described herein, including compression and expansion of timers based on trigger conditions. The memory 2504 may be a non-transitory memory, a transitory memory, a volatile memory (e.g. RAM), or a non-volatile memory (e.g. ROM).

The apparatus 2500 optionally includes a display and/or I/O interface 2508 that may be used to display aspects or a status of the methods described herein (e.g., as one of the methods is being performed or at a subsequent time), or to receive input from a user such as with using a keypad, camera, touchscreen, touch area, microphone, biometric recognition, one or more sensors, etc. The apparatus 2500 includes one or more communication e.g. network (N/W) interfaces (I/F(s)) 2510. The communication I/F(s) 2510 may be wired and/or wireless and communicate over the Internet/other network(s) via any communication technique. The communication I/F(s) 2510 may comprise one or more transmitters and one or more receivers. The communication I/F(s) 2510 may comprise standard well-known components such as an amplifier, filter, frequency-converter, (de)modulator, and encoder/decoder circuitries and one or more antennas.

The apparatus 2500 to implement the functionality of control 2506 and/or signal processing accelerator 2507 may be UE 110, RAN node 170 (e.g. gNB), network element(s) 190, or any of the other apparatuses shown in the other figures, including processing element (10, 1800). Thus, processor 2502 may correspond to processor(s) 120, processor(s) 152 and/or processor(s) 175, memory 2504 may correspond to memory(ies) 125, memory(ies) 155 and/or memory(ies) 171, computer program code 2505 may correspond to computer program code 123, module 140-1, module 140-2, and/or computer program code 153, module 150-1, module 150-2, and/or computer program code 173, and communication I/F(s) 710 may correspond to transceiver 130, antenna(s) 128, transceiver 160, antenna(s) 158, N/W I/F(s) 161, and/or N/W I/F(s) 180. Alternatively, apparatus 2500 may not correspond to either of UE 110, RAN node 170, or network element(s) 190, as apparatus 2500 may be part of a self-organizing/optimizing network (SON) node, such as in a cloud.

The apparatus 2500 may also be distributed throughout the network (e.g. 100) including within and between apparatus 2500 and any network element (such as a network control element (NCE) 190 and/or the RAN node 170 and/or the UE 110) or processing element (10, 1800) or processor array 1602.

Interface 2512 enables data communication between the various items of apparatus 2500, as shown in FIG. 25. For example, the interface 2512 may be one or more buses such as address, data, or control buses, and may include any interconnection mechanism, such as a series of lines on a motherboard or integrated circuit, fiber optics or other optical communication equipment, and the like. Computer program code 2505, including control 2506 and signal processing accelerator 2507 may comprise object-oriented software configured to pass data/messages between objects within computer program code 2505. The apparatus 2500 need not comprise each of the features mentioned, or may comprise other features as well.

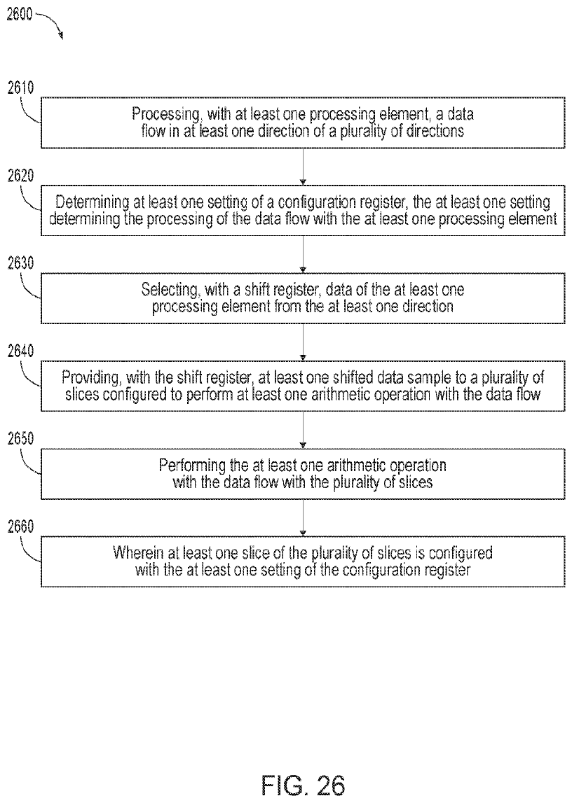

FIG. 26 is an example method 2600 to implement the example embodiments described herein. At 2610, the method includes processing, with at least one processing element, a data flow in at least one direction of a plurality of directions. At 2620, the method includes determining at least one setting of a configuration register, the at least one setting determining the processing of the data flow with the at least one processing element. At 2630, the method includes selecting, with a shift register, data of the at least one processing element from the at least one direction. At 2640, the method includes providing, with the shift register, at least one shifted data sample to a plurality of slices configured to perform at least one arithmetic operation with the data flow. At 2650, the method includes performing the at least one arithmetic operation with the data flow with the plurality of slices. At 2660, the method includes wherein at least one slice of the plurality of slices is configured with the at least one setting of the configuration register.

### The Following Examples (1-94) Are Provided and Described Herein.

Example 1. An apparatus includes at least one processing element configured to process a data flow in at least one direction of a plurality of directions; a configuration register including at least one setting that determines the processing of the data flow with the at least one processing element; and a shift register configured to select data of the at least one processing element from the at least one direction, and to provide at least one shifted data sample to a plurality of slices configured to perform at least one arithmetic operation with the data flow; wherein at least one slice of the plurality of slices is configured with the at least one setting of the configuration register.

Example 2. The apparatus of example 1, wherein the data flow processed in parallel with another data flow within an array of multi-directionally coupled processing elements configured to process the data flow in the plurality of directions.

Example 3. The apparatus of example 2, wherein the at least one processing element within the array is multi-directionally coupled along four cardinal axes and four ordinal axes to a plurality of other processing elements within the array.

Example 4. The apparatus of any of examples 2 to 3, wherein the array of multi-directionally coupled processing elements is memory-less.

Example 5. The apparatus of any of examples 3 to 4, further including: at least one configurable fabric switch of the at least one processing element, the at least one configurable fabric switch configured to couple the at least one processing element to another processing element within the array, and to provide an interface between the at least one processing element and the plurality of slices.

Example 6. The apparatus of example 5, wherein the at least one configurable fabric switch is configured to select among a plurality of egress data ports and a plurality of ingress data ports along the four cardinal axes and the four ordinal axes.

Example 7. The apparatus of example 6, wherein at least two of the egress data ports or at least two of the ingress data ports are combined to transport a real vector or a complex vector.

Example 8. The apparatus of any of examples 1 to 7, wherein the at least one processing element is configured with the configuration register depending on a type of the data flow.

Example 9. The apparatus of any of examples 1 to 8, further including: a first program register file configured to control a first instruction flow within the at least one processing element, the first instruction flow used for arithmetic transfers; and a second program register file configured to control a second instruction flow within the at least one processing element, the second instruction flow used for input and output transfers.

Example 10. The apparatus of example 9, wherein the first instruction flow is separate from and processed in parallel with the second instruction flow within the at least one processing element.

Example 11. The apparatus of any of examples 1 to 10, wherein the shift register includes: at least one ingress multiplexer to select ingress data from the at least one processing element from one of four cardinal axes and four ordinal axes; at least one ingress shift register to shift the ingress data selected with the at least one ingress multiplexer; and at least one shift register multiplexer to select an output of the at least one ingress shift register, the output of the at least one shift register multiplexer configured to be processed with the plurality of slices.

Example 12. The apparatus of example 11, further including a control sequencer configured with the configuration register, the control sequencer including: an arithmetic multiplexer configured to select an output of the at least one ingress shift register, and to provide an operand input to the at least one slice; and selection logic to generate an operand selection line of the arithmetic multiplexer.

Example 13. The apparatus of any of examples 1 to 12, wherein the shift register is used for realizing at least one correlation operation, at least one convolution operation, and at least one covariance operation.

Example 14. The apparatus of any of examples 1 to 13, wherein the shift register is configured to implement a real filter with different lengths or a complex-value filter with different lengths, and is configured to support a filter with multiple input channels.

Example 15. The apparatus of any of examples 1 to 14, wherein the shift register includes a delay line structure configurable with changing connection paths at an input of a plurality of horizontal delay segments, the horizontal delay segments able to be separated, and with selecting filter taps from vertical segments that are passed as operands to the at least one slice.

Example 16. The apparatus of any of examples 1 to 15, further including an adder tree that performs a summation of results from the plurality of slices, the adder tree controlled with at least one input output instruction.

Example 17. The apparatus of example 16, wherein the adder tree is configured to perform a plurality of summations of a plurality of subsets of the results from the plurality of slices.

Example 18. The apparatus of any of examples 1 to 17, wherein the at least one setting of the configuration register is used to preconfigure the at least one slice prior to processing the data flow, depending on a type of the data flow.

Example 19. The apparatus of any of examples 1 to 18, wherein the at least one setting of the configuration register determines at least one of: a number format representation; program instruction behavior; an input and output flow connection configuration; at least one custom value for at least one indirect operator; a functional block configuration; a hardware nested loop control parameter; or a default ingress egress connection.

Example 20. The apparatus of example 19, wherein the number format representation includes at least one of real, complex, fixed-point, or floating-point.

Example 21. The apparatus of any of examples 1 to 20, wherein the at least one setting of the configuration register is updated during processing of the data flow to alter the processing of the data flow or the at least one processing element.

Example 22. The apparatus of any of examples 1 to 21, wherein the configuration register is used to define at least one indirect value for address and counter control, wherein an instruction of the configuration register, with use of the at least one indirect value, includes less bits than a predetermined number of one or more bits.

Example 23. The apparatus of any of examples 1 to 22, wherein an output of the plurality of slices is processed with an asymmetric first in first out data structure.

Example 24. The apparatus of example 23, wherein the asymmetric first in first out data structure is designed to instantaneously capture results from the plurality of slices, and to provide temporary storage pending for transfer programmed with at least one input output instruction.

Example 25. The apparatus of any of examples 23 to 24, wherein the asymmetric first in first out data structure is configured to reorder at least one result from the at least one slice matching with the data flow.

Example 26. The apparatus of any of examples 23 to 25, wherein the configuration register is used to define at least one pointer for the asymmetric first in first out data structure, and the configuration register is used for simple sequence repeat order sequencing.

Example 27. The apparatus of any of examples 23 to 26, wherein the asymmetric first in first out data structure includes: a low word output multiplexer configured to determine a first selection of at least one value of the plurality of slices; a high word output multiplexer configured to determine a second selection of the at least one value of the plurality of slices; and an operand connection to concatenate the first selection from the low word output multiplexer with the second selection from the high word output multiplexer.

Example 28. The apparatus of any of examples 23 to 27, wherein the asymmetric first in first out data structure is configured to receive as input first data having a first bit width and return as output second data having a second bit width, the first bit width being different from the second bit width.

Example 29. The apparatus of any of examples 1 to 28, wherein the configuration register includes at least one bit field that controls a tiered nested loop structure configured to program the at least one processing element.

Example 30. The apparatus of example 29, wherein the tiered nested loop structure includes: a first tier including initial instructions and post outer loop instructions; a second tier including outer loop instructions and post mid loop instructions; a third tier including mid loop instructions and post inner loop instructions; and a fourth tier including inner loop instructions.

Example 31. The apparatus of any of examples 29 to 30, wherein the tiered nested loop structure is configured to program the at least one processing element so that the data flow is processed without conditional branch instructions.

Example 32. The apparatus of any of examples 29 to 31, wherein the configuration register is used to configure a loop count at a tier of the tiered nested loop structure.

Example 33. The apparatus of any of examples 1 to 32, wherein the at least one slice is configured to process a finite impulse response filter or a correlation filter.

Example 34. The apparatus of any of examples 1 to 33, wherein the at least one setting of the configuration register determines a channel and tap configuration of a real filter and a complex filter.

Example 35. The apparatus of any of examples 1 to 34, wherein the at least one slice includes: a first operand bus configured to source data from at least one ingress port and the shift register; a second operand bus configured to source data from an operand register and a coefficient memory.

Example 36. The apparatus of example 35, wherein the at least one setting of the configuration register determines whether the first operand bus sources data from the at least one ingress port or the shift register.

Example 37. The apparatus of any of examples 35 to 36, wherein the at least one setting of the configuration register determines whether the second operand bus sources data from the operand register or the coefficient memory.

Example 38. The apparatus of any of examples 1 to 37, wherein the at least one slice includes: a plurality of add and multiply blocks; a plurality of adder blocks to add an output from one of the add and multiply blocks; at least one adder to combine the output of the plurality of adder blocks; and an accumulation register to accumulate at least one result of the at least one adder.

Example 39. The apparatus of any of examples 1 to 38, wherein at least one feature of the at least one slice is configured to be placed in a low power state when the at least one feature is not used for processing the data flow.

Example 40. The apparatus of any of examples 1 to 39, wherein the at least one slice is configured to be placed in a low power state when the at least one slice is not used for processing the data flow.

Example 41. The apparatus of any of examples 1 to 40, wherein the configuration register is configured to allow a user to preconfigure the at least one slice before the data flow is processed.

Example 42. A method includes processing, with at least one processing element, a data flow in at least one direction of a plurality of directions; determining at least one setting of a configuration register, the at least one setting determining the processing of the data flow with the at least one processing element; selecting, with a shift register, data of the at least one processing element from the at least one direction; providing, with the shift register, at least one shifted data sample to a plurality of slices configured to perform at least one arithmetic operation with the data flow; and performing the at least one arithmetic operation with the data flow with the plurality of slices; wherein at least one slice of the plurality of slices is configured with the at least one setting of the configuration register.

Example 43. An apparatus includes at least one processor; and at least one memory including computer program code; wherein the at least one memory and the computer program code are configured to, with the at least one processor, cause the apparatus at least to: process, with at least one processing element, a data flow in at least one direction of a plurality of directions; determine at least one setting of a configuration register, the at least one setting determining the processing of the data flow with the at least one processing element; select, with a shift register, data of the at least one processing element from the at least one direction; provide, with the shift register, at least one shifted data sample to a plurality of slices configured to perform at least one arithmetic operation with the data flow; and perform the at least one arithmetic operation with the data flow with the plurality of slices; wherein at least one slice of the plurality of slices is configured with the at least one setting of the configuration register.

Example 44. An apparatus including means for processing, with at least one processing element, a data flow in at least one direction of a plurality of directions; means for determining at least one setting of a configuration register, the at least one setting determining the processing of the data flow with the at least one processing element; means for selecting, with a shift register, data of the at least one processing element from the at least one direction; means for providing, with the shift register, at least one shifted data sample to a plurality of slices configured to perform at least one arithmetic operation with the data flow; and means for performing the at least one arithmetic operation with the data flow with the plurality of slices; wherein at least one slice of the plurality of slices is configured with the at least one setting of the configuration register.

Example 45. An integrated circuit comprising at least one processing element configured to process a data flow in at least one direction of a plurality of directions; a configuration register comprising at least one setting that determines the processing of the data flow with the at least one processing element; and a shift register configured to select data of the at least one processing element from the at least one direction, and to provide at least one shifted data sample to a plurality of slices configured to perform at least one arithmetic operation with the data flow; wherein at least one slice of the plurality of slices is configured with the at least one setting of the configuration register.

Example 46. An apparatus includes an array of multi-directionally coupled processing elements configured to process a data flow in a plurality of directions, the data flow processed in parallel with another data flow within the array; wherein at least one processing element within the array is multi-directionally coupled along four cardinal axes and four ordinal axes to a plurality of other processing elements within the array; and at least one configurable fabric switch of the at least one processing element, the at least one configurable fabric switch configured to couple the at least one processing element to another processing element within the array.

Example 47. The apparatus of example 46, wherein the at least one configurable fabric switch is configured to select among a plurality of egress data ports and a plurality of ingress data ports along the four cardinal axes and the four ordinal axes.

Example 48. The apparatus of example 47, wherein at least two of the egress data ports or at least two of the ingress data ports are combined to transport a real vector or a complex vector.

Example 49. The apparatus of any of examples 46 to 48, wherein the array of multi-directionally coupled processing elements is memory-less.

Example 50. The apparatus of any of examples 46 to 49, wherein the at least one processing element is configured depending on a type of the data flow.

Example 51. The apparatus of any of examples 46 to 50, further including a plurality of slices configured to perform at least one arithmetic operation with the data flow, wherein the at least one configurable fabric switch provides an interface between the at least one processing element and the plurality of slices.

Example 52. An apparatus includes an array of multi-directionally coupled processing elements configured to process a data flow in a plurality of directions, the data flow processed in parallel with another data flow within the array; and a configuration register including at least one setting that determines the processing of the data flow with at least one processing element; wherein the at least one processing element is configured with the configuration register depending on a type of the data flow.

Example 53. The apparatus of example 52, further including a plurality of slices configured to perform at least one arithmetic operation with the data flow, wherein at least one slice of the plurality of slices is configured with the at least one setting of the configuration register.

Example 54. The apparatus of example 53, wherein the configuration register is configured to allow a user to preconfigure the at least one slice before the data flow is processed.

Example 55. The apparatus of any of examples 53 to 54, wherein the at least one setting of the configuration register is used to preconfigure the at least one slice prior to processing the data flow, depending on the type of the data flow.

Example 56. The apparatus of any of examples 53 to 55, wherein the at least one slice includes: a first operand bus configured to source data from at least one ingress port and a shift register; a second operand bus configured to source data from an operand register and a coefficient memory.

Example 57. The apparatus of example 56, wherein the at least one setting of the configuration register determines whether the first operand bus sources data from the at least one ingress port or the shift register.

Example 58. The apparatus of any of examples 56 to 57, wherein the at least one setting of the configuration register determines whether the second operand bus sources data from the operand register or the coefficient memory.

Example 59. The apparatus of any of examples 53 to 58, wherein the configuration register is used to define at least one pointer for an asymmetric first in first out data structure that processes an output of the plurality of slices, and the configuration register is used for simple sequence repeat order sequencing.

Example 60. The apparatus of any of examples 52 to 59, wherein the at least one setting of the configuration register determines at least one of: a number format representation, the number format representation including at least one of real, complex, fixed-point, or floating-point; program instruction behavior; an input and output flow connection configuration; at least one custom value for at least one indirect operator; a functional block configuration; a hardware nested loop control parameter; or a default ingress egress connection.

Example 61. The apparatus of any of examples 52 to 60, wherein the at least one setting of the configuration register is updated during processing of the data flow to alter the processing of the data flow or the at least one processing element.

Example 62. The apparatus of any of examples 52 to 61, wherein the configuration register is used to define at least one indirect value for address and counter control, wherein an instruction of the configuration register, with use of the at least one indirect value, includes less bits than a predetermined number of one or more bits.

Example 63. The apparatus of any of examples 52 to 62, wherein the configuration register includes at least one bit field that controls a tiered nested loop structure configured to program the at least one processing element.

Example 64. The apparatus of example 63, wherein the configuration register is used to configure a loop count at a tier of the tiered nested loop structure.

Example 65. The apparatus of any of examples 52 to 64, wherein the at least one setting of the configuration register determines a channel and tap configuration of a real filter and a complex filter.

Example 66. An apparatus includes at least one processing element configured to process a data flow in at least one direction of a plurality of directions; a first program register file configured to control a first instruction flow within the at least one processing element, the first instruction flow used for arithmetic transfers; and a second program register file configured to control a second instruction flow within the at least one processing element, the second instruction flow used for input and output transfers; wherein the first instruction flow is separate from and processed in parallel with the second instruction flow within the at least one processing element.

Example 67. The apparatus of example 66, wherein a tiered nested loop structure is configured to program the at least one processing element.

Example 68. The apparatus of example 67, wherein the tiered nested loop structure includes: a first tier including initial instructions and post outer loop instructions; a second tier including outer loop instructions and post mid loop instructions; a third tier including mid loop instructions and post inner loop instructions; and a fourth tier including inner loop instructions.

Example 69. The apparatus of any of examples 67 to 68, wherein the tiered nested loop structure is configured to program the at least one processing element so that the data flow is processed without conditional branch instructions.

Example 70. The apparatus of any of examples 67 to 69, wherein a configuration register is used to configure a loop count at a tier of the tiered nested loop structure.

Example 71. An apparatus includes at least one processing element configured to process a data flow in at least one direction of a plurality of directions; and a shift register configured to select data of the at least one processing element from the at least one direction, and to provide at least one shifted data sample to a plurality of slices configured to perform at least one arithmetic operation with the data flow.

Example 72. The apparatus of example 71, wherein the shift register includes: at least one ingress multiplexer to select ingress data from the at least one processing element from one of four cardinal axes and four ordinal axes; at least one ingress shift register to shift the ingress data selected with the at least one ingress multiplexer; and at least one shift register multiplexer to select an output of the at least one ingress shift register, the output of the at least one shift register multiplexer configured to be processed with the plurality of slices.

Example 73. The apparatus of any of examples 71 to 72, further including: a configuration register including at least one setting that determines the processing of the data flow with the at least one processing element; a control sequencer configured with the configuration register, the control sequencer including an arithmetic multiplexer configured to select an output of the at least one ingress shift register and to provide an operand input to at least one slice of the plurality of slices, wherein the control sequencer further includes selection logic to generate an operand selection line of the arithmetic multiplexer.

Example 74. The apparatus of any of examples 71 to 73, wherein the shift register is used for realizing at least one correlation operation, at least one convolution operation, and at least one covariance operation.

Example 75. The apparatus of any of examples 71 to 74, wherein the shift register is configured to implement a real with different lengths or a complex-value filter with different lengths, and is configured to support a filter with multiple input channels.

Example 76. The apparatus of any of examples 71 to 75, wherein the shift register includes a delay line structure configurable with changing connection paths at an input of a plurality of horizontal delay segments, the horizontal delay segments able to be separated, and with selecting filter taps from vertical segments that are passed as operands to at least one slice of the plurality of slices.

Example 77. An apparatus includes a plurality of slices configured to perform at least one arithmetic operation with a data flow; a configuration register including at least one setting, wherein at least one slice of the plurality of slices is configured with the at least one setting of the configuration register; an asymmetric first in first out data structure to process an output of the plurality of slices; and an adder tree that performs a summation of results from the plurality of slices, the adder tree controlled with at least one input output instruction.

Example 78. The apparatus of example 77, wherein the at least one setting of the configuration register is used to preconfigure the at least one slice prior to processing the data flow, depending on a type of the data flow.

Example 79. The apparatus of example 78, wherein the adder tree is configured to perform a plurality of summations of a plurality of subsets of the results from the plurality of slices.

Example 80. The apparatus of any of examples 77 to 79, wherein the configuration register is used to define at least one pointer for the asymmetric first in first out data structure, and the configuration register is used for simple sequence repeat order sequencing.

Example 81. The apparatus of any of examples 77 to 80, wherein the asymmetric first in first out data structure includes: a low word output multiplexer configured to determine a first selection of at least one value of the plurality of slices; a high word output multiplexer configured to determine a second selection of the at least one value of the plurality of slices; and an operand connection to concatenate the first selection from the low word output multiplexer with the second selection from the high word output multiplexer.

Example 82. The apparatus of any of examples 77 to 81, wherein the asymmetric first in first out data structure is configured to receive as input first data having a first bit width and return as output second data having a second bit width, the first bit width being different from the second bit width.

Example 83. The apparatus of any of examples 77 to 81, wherein the at least one slice is configured to process a finite impulse response filter or a correlation filter.

Example 84. The apparatus of any of examples 77 to 83, wherein the at least one slice includes: a first operand bus configured to source data from at least one ingress port and a shift register; a second operand bus configured to source data from an operand register and a coefficient memory.

Example 85. The apparatus of example 84, wherein the at least one setting of the configuration register determines whether the first operand bus sources data from the at least one ingress port or the shift register.

Example 86. The apparatus of any of examples 84 to 85, wherein the at least one setting of the configuration register determines whether the second operand bus sources data from the operand register or the coefficient memory.

Example 87. The apparatus of any of examples 77 to 86, wherein the at least one slice includes: a plurality of add and multiply blocks; a plurality of adder blocks to add an output from one of the add and multiply blocks; at least one adder to combine the output of the plurality of adder blocks; and an accumulation register to accumulate at least one result of the at least one adder.

Example 88. The apparatus of any of examples 77 to 87, wherein the configuration register is configured to allow a user to preconfigure the at least one slice before the data flow is processed.

Example 89. The apparatus of any of examples 77 to 88, wherein the at least one setting of the configuration register determines a number format representation, wherein the number format representation includes at least one of real, complex, fixed-point, or floating-point.

Example 90. The apparatus of any of examples 77 to 89, wherein at least one feature of the at least one slice is configured to be placed in a low power state when the at least one feature is not used for processing the data flow.

Example 91. The apparatus of any of examples 77 to 90, wherein the at least one slice is configured to be placed in a low power state when the at least one slice is not used for processing the data flow.

Example 92. The apparatus of any of examples 77 to 91, wherein the asymmetric first in first out data structure is designed to instantaneously capture results from the plurality of slices, and to provide temporary storage pending for transfer programmed with at least one input output instruction.

Example 93. The apparatus of any of examples 77 to 92, wherein the asymmetric first in first out data structure is configured to reorder at least one result from the at least one slice matching with the data flow.

Example 94. The apparatus of any of examples 2 to 41, wherein the data flow is processed in a first direction within the array using a first subset of processing elements, and another data flow is processed in a second direction within the array using a second subset of processing elements, wherein the first direction is different from the second direction, and the first subset of processing elements is different from the second subset of processing elements.

References to a ‘computer’, ‘processor’, etc. should be understood to encompass not only computers having different architectures such as single/multi-processor architectures and sequential or parallel architectures but also specialized circuits such as field-programmable gate arrays (FPGAs), application specific circuits (ASICs), signal processing devices and other processing circuitry. References to computer program, instructions, code etc. should be understood to encompass software for a programmable processor or firmware such as, for example, the programmable content of a hardware device whether instructions for a processor, or configuration settings for a fixed-function device, gate array or programmable logic device etc.

As used herein, the term ‘circuitry’ may refer to the following: (a) hardware circuit implementations, such as implementations in analog and/or digital circuitry, and (b) combinations of circuits and software (and/or firmware), such as (as applicable): (i) a combination of processor(s) or (ii) portions of processor(s)/software including digital signal processor(s), software, and memory(ies) that work together to cause an apparatus to perform various functions, and (c) circuits, such as a microprocessor(s) or a portion of a microprocessor(s), that require software or firmware for operation, even if the software or firmware is not physically present. As a further example, as used herein, the term ‘circuitry’ would also cover an implementation of merely a processor (or multiple processors) or a portion of a processor and its (or their) accompanying software and/or firmware. The term ‘circuitry’ would also cover, for example and if applicable to the particular element, a baseband integrated circuit or applications processor integrated circuit for a mobile phone or a similar integrated circuit in a server, a cellular network device, or another network device.

In the figures, arrows between individual blocks represent operational couplings there-between as well as the direction of data flows on those couplings.

It should be understood that the foregoing description is only illustrative. Various alternatives and modifications may be devised by those skilled in the art. For example, features recited in the various dependent claims could be combined with each other in any suitable combination(s). In addition, features from different example embodiments described above could be selectively combined into a new example embodiment. Accordingly, this description is intended to embrace all such alternatives, modifications and variances which fall within the scope of the appended claims.

The following acronyms and abbreviations that may be found in the specification and/or the drawing figures are defined as follows (the abbreviations and acronyms may be appended with each other or with other characters using e.g. a dash, hyphen, or number):
4G fourth generation
5G fifth generation
5GC 5G core network
6G sixth generation
A (FIG. 18 (1821)) Operand Register(A) input to Operand 2 bus. (FIG. 14 (1420), 15, 19, 20, 23 (1820)) Identifier for Operand 1 vector element. (FIGS. 10, 12, 23 (1826)) Identifier for shift register bus path. (FIG. 7) program instruction parameter for Auto Increment address pointer.
ACC accumulator
ADC add-accumulate program instruction, or add with carry, depending on context
ADD Add program instruction
addi add immediate
ALU arithmetic logic unit
AMF access and mobility management function
ASIC application-specific integrated circuit
AU arithmetic unit
B (FIG. 14 (1420), 15, 19, 20, 23 (1820)) Identifier for Operand 1 vector element. (FIGS. 10, 12, 23 (1826)) Identifier for shift register bus path. (FIG. 7) program instruction parameter to set Base Address for CMEM.
BGE branch instruction comparing two values (signed)
C (FIG. 14 (1426), FIG. 18 (1821)) Coefficient memory input to Operand 2 bus. (FIG. 14 (1420), 15, 19, 20, 23 (1820)) Identifier for Operand 1 vector element. (FIGS. 10, 12, 23 (1826)) Identifier for shift register bus path. (FIG. 7) program instruction parameter to swap CMEM and Shadow CMEM functions.
CLK clock
CMEM coefficient memory
cmplx complex
Cnt/CNT count
CONFIG Configuration change operand program instruction
Const constant
Cplx complex
CPM control plane management
CPU central processing unit
CSR control and status register
ctrl control
CU central unit or centralized unit
cWAFER configurable wafer
D (FIGS. 10, 12, 23) Identifier for shift register bus path. (FIG. 14 (1420), 15, 19, 20, 23 (1820)) Identifier for Operand 1 vector element. (FIG. 7) program instruction parameter to select destination for Read operation
DEBUG Debugging program instruction
dest destination
DFE decision feedback equalizer
DMA direct memory access
DSP digital signal processor
DW (FIG. 21) Double word format 80-bits.
E (FIGS. 10, 12, 23) Identifier for shift register bus path. (FIG. 7) program instruction parameter to enable Shift register debugging mode.
EE east
en enable or enabled
eNB evolved Node B (e.g., an LTE base station)
EN-DC E-UTRAN new radio—dual connectivity
en-gNB node providing NR user plane and control plane protocol terminations towards the UE, and acting as a secondary node in EN-DC
E-UTRA evolved universal terrestrial radio access, i.e., the LTE radio access technology
E-UTRAN E-UTRA network
EX RISC-V architecture execution pipeline phases—Execute phase
exp exponent
E(,) (FIGS. 2, 3) cluster PE Tile identifier T(x, y), x-column and y-row location within a Cluster. Refer also to FIG. 17.
F (FIGS. 10, 12, 23) Identifier for shift register bus path. (FIG. 7) program instruction parameter to flip order of output results.
F1 interface between the CU and the DU
FCS format configuration select
FEQ full equations
FIFO or FiFo first in first out
FIR finite impulse response
FLP Floating Point format—e.g. FIG. 21 and FIG. 10
FPGA field-programmable gate array
FSM finite state machine
FxP fixed point
gNB base station for 5G/NR, i.e., a node providing NR user plane and control plane protocol terminations towards the UE, and connected via the NG interface to the 5GC
GNSS global navigation satellite system
GPU graphics processing unit
H high
HCI host control interpreter
hwloop hardware loop
I (FIG. 7) Outer Loop repeating times (FIG. 14 (1420), FIG. 18 (1821)) Ingress Port input to Operand 1 bus.
IAB integrated access and backhaul
ID instruction decode
IJ Indicates an instruction is inside both the I and J hardware loop structure
IJK Indicates an instruction is inside the I, J, and K hardware loop structure.
I/F interface
IF instruction fetch
IM RISC-V architecture execution pipeline phases-Immediate value phase
Imag imaginary
IN ingress
Inc increment
init/Init/INIT initialization or initialize
I/O or IO input output
IOB I/O element on bottom of array for data samples and results
IOL I/O element on left of array to load the array memories
IOT I/O element on top of array for data samples and results
ISA instruction set architecture
j jump
J (FIG. 14 (including 1426), 15, 19, 20, 23) Identifier for Operand 2 vector element. (FIG. 7) Mid Loop repeating times.
K (FIG. 14 (including 1426), 15, 19, 20, 23) Identifier for Operand 2 vector element. (FIG. 7) Inner Loop repeating times.
L (FIG. 14 (including 1426), 15, 19, 20, 23) Identifier for Operand 2 vector element. (FIG. 7) program instruction parameter to select signal port
L1 layer 1
LCR long configuration register
LD Load Data bus
LDM load data memory
li load immediate
LMF location management function
LOAD Load Accumulator program instruction
LSU load store unit
LTE long term evolution (4G)
M (FIG. 14 (including 1426), 15, 19, 20, 23) Identifier for Operand 2 vector element.
MAC Multiply Accumulate program instruction, or medium access control as relates to the description of FIG. 24
MCLSU microcoded load store unit
MIMD multiple instruction multiple data
MIMO multiple-input and multiple-output
MME mobility management entity
MPY multiply program instruction
MRO mobility robustness optimization
MULT multiply
mux or MUX multiplexer
N (FIG. 7) program instruction parameter to select number of FIFO and adder tree outputs
NCE network control element
NE northeast
Neg negative
ng or NG new generation
ng-eNB new generation eNB
NG-RAN new generation radio access network
NN north
NOP no operation program instruction
NR new radio (5G)
N/W network
NW network, or northwest depending on context
O (FIG. 7) program instruction parameter to select Operand 2 source
OBI open bus interface
Op operation
OPR operand
P (FIG. 7) program instruction parameter to Pulse the SSR shift enable
PC (FIG. 16) RISC-V architecture execution pipeline phases—program counter instruction fetch phase
PDA personal digital assistant
PDCP packet data convergence protocol
PE processing element
PHY physical layer
PMEM program memory
PTR pointer
R (FIG. 7) program instruction parameter Repeat instruction count.
RAM random access memory
RAN radio access network
Rd read
RDADD Add Tree Read program instruction
RdbCL Read Data Bus for Cluster
RDFIFO FIFO read program instruction
ReBase Reload base address pointer for CMEM
reg/REG register
regs registers
RF (FIG. 16) RISC-V architecture execution pipeline phases-Register Fetch phase
RISC reduced instruction set computer
RISC-V RISC five
RLC radio link control
ROM read-only memory
RRC radio resource control (protocol)
RU radio unit
Rx receiver or reception
S (FIG. 7) program instruction parameter Accumulator load source. FIG. 14 (1422), FIG. 18 (1821)) Sample Shift register input to Operand 1 bus. (FIG. 14 (1431), 15, 19, 20, 23) Identifier for AU result vector element
SCR Static Control register (an earlier name for the Long Control Word)
SDM streaming data memory
SE southeast
sel/Sel select
WR-SFT control bit in the LCR to enable the auto shift into the SSR
SGW serving gateway
SIM system interface memory
SIMD sing instruction multiple data
SL slice
SMF session management function
SON self-organizing/optimizing network
Sr or SR shift register
Src source
SS south
SSR sample shift register
Sw switch
SW southwest
T (FIG. 7) program instruction parameter selects targeted registers. (FIG. 14 (including 1431), 15, 19, 20, 23) Identifier for AU result vector element
T(,) (FIGS. 2, 3) unique PE Tile identifier T(x, y), x-column and y-row location in the PE array.
TA timing advance
TCM tightly coupled memory
TRP transmission reception point
Tx transmitter or transmission
U (FIGS. 15, 19, 20, 23) Identifier for AU result vector element
UAV unmanned aerial vehicle
UDE unified data editor
UDU unified data unit
UE user equipment (e.g., a wireless, typically mobile device)
UPF user plane function
V (FIG. 7) program instruction parameter Immediate value count. (FIGS. 15, 19, 20, 23) Identifier for AU result vector element
VLIW very long instruction word
W write
WB RISC-V architecture execution pipeline phases—Writeback to Memory phase
WdbCL Write Data Bus for Cluster
WdICL Write Load data bus to Cluster
WdtCL Write Data Bus for Cluster
WF (FIGS. 21, 22) Word Format 40-bits
wr/Wr/WR write
WW west
X (FIG. 14, FIG. 18 (1821)) Ingress port input to Operand 2 bus.
X2 network interface between RAN nodes and between RAN and the core network
XFR transfer
Xn network interface between NG-RAN nodes

1. An apparatus comprising:
at least one processing element configured to process a data flow in at least one direction of a plurality of directions;
a configuration register comprising at least one setting that determines the processing of the data flow with the at least one processing element; and
a shift register configured to select data of the at least one processing element from the at least one direction, and to provide at least one shifted data sample to a plurality of slices configured to perform at least one arithmetic operation with the data flow;
wherein at least one slice of the plurality of slices is configured with the at least one setting of the configuration register,
wherein the data flow processed in parallel with another data flow within an array of multi-directionally coupled processing elements configured to process the data flow in the plurality of directions, and
wherein the array of multi-directionally coupled processing elements is memory-less.

2. (canceled)

3. The apparatus of claim 1, wherein the at least one processing element within the array is multi-directionally coupled along four cardinal axes and four ordinal axes to a plurality of other processing elements within the array.

4. (canceled)

5. The apparatus of claim 3, further comprising:
at least one configurable fabric switch of the at least one processing element, the at least one configurable fabric switch configured to couple the at least one processing element to another processing element within the array, and to provide an interface between the at least one processing element and the plurality of slices.

6. The apparatus of claim 5, wherein the at least one configurable fabric switch is configured to select among a plurality of egress data ports and a plurality of ingress data ports along the four cardinal axes and the four ordinal axes.

7. The apparatus of claim 6, wherein at least two of the egress data ports or at least two of the ingress data ports are combined to transport a real vector or a complex vector.

8. The apparatus of claim 1, wherein the at least one processing element is configured with the configuration register depending on a type of the data flow.

9. The apparatus of claim 1, further comprising:
a first program register file configured to control a first instruction flow within the at least one processing element, the first instruction flow used for arithmetic transfers; and
a second program register file configured to control a second instruction flow within the at least one processing element, the second instruction flow used for input and output transfers.

10. The apparatus of claim 9, wherein the first instruction flow is separate from and processed in parallel with the second instruction flow within the at least one processing element.

11. The apparatus of claim 1, wherein the shift register comprises:
at least one ingress multiplexer to select ingress data from the at least one processing element from one of four cardinal axes and four ordinal axes;
at least one ingress shift register to shift the ingress data selected with the at least one ingress multiplexer; and
at least one shift register multiplexer to select an output of the at least one ingress shift register, the output of the at least one shift register multiplexer configured to be processed with the plurality of slices.

12. The apparatus of claim 11, further comprising a control sequencer configured with the configuration register, the control sequencer comprising:
an arithmetic multiplexer configured to select an output of the at least one ingress shift register, and to provide an operand input to the at least one slice; and
selection logic to generate an operand selection line of the arithmetic multiplexer.

13. The apparatus of claim 1, wherein the shift register is used for realizing at least one correlation operation, at least one convolution operation, and at least one covariance operation.

14. The apparatus of claim 1, wherein the shift register is configured to implement a real filter with different lengths or a complex-value filter with different lengths, and is configured to support a filter with multiple input channels.

15. The apparatus of claim 1, wherein the shift register comprises a delay line structure configurable with changing connection paths at an input of a plurality of horizontal delay segments, the horizontal delay segments able to be separated, and with selecting filter taps from vertical segments that are passed as operands to the at least one slice.

16. The apparatus of claim 1, further comprising an adder tree that performs a summation of results from the plurality of slices, the adder tree controlled with at least one input output instruction.

17. The apparatus of claim 16, wherein the adder tree is configured to perform a plurality of summations of a plurality of subsets of the results from the plurality of slices.

18-70. (canceled)

71. An apparatus comprising:
at least one processing element configured to process a data flow in at least one direction of a plurality of directions; and
a shift register configured to select data of the at least one processing element from the at least one direction, and to provide at least one shifted data sample to a plurality of slices configured to perform at least one arithmetic operation with the data flow,
wherein the shift register comprises:
at least one ingress multiplexer to select ingress data from the at least one processing element from one of four cardinal axes and four ordinal axes;
at least one ingress shift register to shift the ingress data selected with the at least one ingress multiplexer; and
at least one shift register multiplexer to select an output of the at least one ingress shift register, the output of the at least one shift register multiplexer configured to be processed with the plurality of slices.

72. (canceled)

73. The apparatus of claim 71, further comprising:
a configuration register comprising at least one setting that determines the processing of the data flow with the at least one processing element;
a control sequencer configured with the configuration register, the control sequencer comprising an arithmetic multiplexer configured to select an output of the at least one ingress shift register and to provide an operand input to at least one slice of the plurality of slices, wherein the control sequencer further comprises selection logic to generate an operand selection line of the arithmetic multiplexer.

74. The apparatus of claim 71, wherein the shift register is used for realizing at least one correlation operation, at least one convolution operation, and at least one covariance operation.

75. The apparatus of claim 71, wherein the shift register is configured to implement a real with different lengths or a complex-value filter with different lengths, and is configured to support a filter with multiple input channels.

76. The apparatus of claim 71, wherein the shift register comprises a delay line structure configurable with changing connection paths at an input of a plurality of horizontal delay segments, the horizontal delay segments able to be separated, and with selecting filter taps from vertical segments that are passed as operands to at least one slice of the plurality of slices.

77-94. (canceled)
